(19) United States
(12) Patent Application Publication
(10) Pub. No.: US 2025/0107069 A1
(43) Pub. Date: Mar. 27, 2025

(54) SEMICONDUCTOR DEVICE AND SEMICONDUCTOR MEMORY DEVICE

(71) Applicant: Kioxia Corporation, Tokyo (JP)

(72) Inventors: Takeru MAEDA, Yokkaichi Mie (JP); Sakuya KANEKO, Yokkaichi Mie (JP); Kenichiro TORATANI, Fujisawa Kanagawa (JP); Takafumi OCHIAI, Kuwana Mie (JP); Kazuhiro MATSUO, Kuwana Mie (JP); Masaya TODA, Yokkaichi Mie (JP); Ha HOANG, Kuwana Mie (JP); Kotaro NODA, Yokkaichi Mie (JP)

(21) Appl. No.: 18/884,101

(22) Filed: Sep. 12, 2024

(30) Foreign Application Priority Data
Sep. 21, 2023 (JP) 2023-156463

(51) Int. Cl. H10B 12/00; H01L 29/786

(52) U.S. Cl. CPC H10B 12/33; H10D 1/716; H10D 30/6756

(57) ABSTRACT

According to one embodiment a semiconductor device includes an oxide semiconductor column that extends in a first direction. A first electrode contacts a first end of the oxide semiconductor column and a second electrode contacts a second end. A gate electrode surrounds a portion of the oxide semiconductor column. A first insulating film is between the gate electrode and the oxide semiconductor column. A second insulating film is between the gate electrode and the first electrode in the first direction and surrounds the oxide semiconductor column via the first insulating film. A region in which at least a part of the oxide semiconductor column is accommodated is formed by the gate electrode and the second insulating film, and the region has a stepped surface facing towards the second electrode.

### CROSS-REFERENCE TO RELATED APPLICATIONS

This application is based upon and claims the benefit of priority from Japanese Patent Application No. 2023-156463, filed Sep. 21, 2023, the entire contents of which are incorporated herein by reference.

### FIELD

Embodiments described herein relate generally to a semiconductor device and a semiconductor memory device.

### BACKGROUND

Some semiconductor elements use metal oxides comprising indium and tin for electrodes.

In the manufacturing process of semiconductor elements in which metal oxides are used for electrodes, there is a need for a technology for manufacturing high-quality semiconductor devices.

### BRIEF DESCRIPTION OF THE DRAWINGS

FIG. 1 is a circuit diagram for illustrating an example of a circuit configuration of a memory cell array according to a first embodiment.

FIG. 2 is a cross-sectional schematic view for illustrating an example structure of a semiconductor memory device according to the first embodiment, showing a cross-sectional view parallel to ZX plane.

FIG. 3 is a cross-sectional schematic view for illustrating an example structure of a semiconductor device according to the first embodiment, showing a cross-sectional view parallel to ZX plane of a semiconductor device of a first example of the first embodiment.

FIG. 4 is a cross-sectional schematic view for illustrating an example structure of the semiconductor device according to the first embodiment, showing a cross-sectional view parallel to YZ plane of the semiconductor device of the first example of the first embodiment.

FIG. 5 is a cross-sectional view taken along cut line V-V shown in FIGS. 3 and 4.

FIG. 6 is a cross-sectional view parallel to ZX plane showing a manufacturing process of the semiconductor device of the first example of the first embodiment.

FIG. 7 is a cross-sectional view parallel to YZ plane showing the manufacturing process of the semiconductor device of the first example of the first embodiment.

FIG. 8 is a cross-sectional view parallel to ZX plane showing the manufacturing process of the semiconductor device of the first example of the first embodiment.

FIG. 9 is a cross-sectional view parallel to YZ plane showing the manufacturing process of the semiconductor device of the first example of the first embodiment.

FIG. 10 is a cross-sectional view parallel to ZX plane showing the manufacturing process of the semiconductor device of the first example of the first embodiment.

FIG. 11 is a cross-sectional view parallel to YZ plane showing the manufacturing process of the semiconductor device of the first example of the first embodiment.

FIG. 12 is a cross-sectional view parallel to ZX plane showing the manufacturing process of the semiconductor device of the first example of the first embodiment.

FIG. 13 is a cross-sectional view parallel to YZ plane showing the manufacturing process of the semiconductor device of the first example of the first embodiment.

FIG. 14 is a cross-sectional view parallel to ZX plane showing the manufacturing process of the semiconductor device of the first example of the first embodiment.

FIG. 15 is a cross-sectional view parallel to YZ plane showing the manufacturing process of the semiconductor device of the first example of the first embodiment.

FIG. 16 is a cross-sectional view parallel to ZX plane showing the manufacturing process of the semiconductor device of the first example of the first embodiment.

FIG. 17 is a cross-sectional view parallel to YZ plane showing the manufacturing process of the semiconductor device of the first example of the first embodiment.

FIG. 18 is a cross-sectional view parallel to ZX plane showing the manufacturing process of the semiconductor device of the first example of the first embodiment.

FIG. 19 is a cross-sectional view parallel to YZ plane showing the manufacturing process of the semiconductor device of the first example of the first embodiment.

FIG. 20 is a cross-sectional view parallel to ZX plane showing the manufacturing process of the semiconductor device of the first example of the first embodiment.

FIG. 21 is a cross-sectional view parallel to YZ plane showing the manufacturing process of the semiconductor device of the first example of the first embodiment.

FIG. 22 is a cross-sectional view parallel to ZX plane showing the manufacturing process of the semiconductor device of the first example of the first embodiment.

FIG. 23 is a cross-sectional view parallel to YZ plane showing the manufacturing process of the semiconductor device of the first example of the first embodiment.

FIG. 24 is a cross-sectional view parallel to ZX plane showing the manufacturing process of the semiconductor device of the first example of the first embodiment.

FIG. 25 is a cross-sectional view parallel to YZ plane showing the manufacturing process of the semiconductor device of the first example of the first embodiment.

FIG. 26 is a cross-sectional view parallel to ZX plane showing the manufacturing process of the semiconductor device of the first example of the first embodiment.

FIG. 27 is a cross-sectional view parallel to YZ plane showing the manufacturing process of the semiconductor device of the first example of the first embodiment.

FIG. 28 is a cross-sectional view parallel to ZX plane showing the manufacturing process of the semiconductor device of the first example of the first embodiment.

FIG. 29 is a cross-sectional view parallel to YZ plane showing the manufacturing process of the semiconductor device of the first example of the first embodiment.

FIG. 30 is a cross-sectional view parallel to ZX plane showing the manufacturing process of the semiconductor device of the first example of the first embodiment.

FIG. 31 is a cross-sectional view parallel to YZ plane showing the manufacturing process of the semiconductor device of the first example of the first embodiment.

FIG. 32 is a cross-sectional view parallel to ZX plane showing the manufacturing process of the semiconductor device of the first example of the first embodiment.

FIG. 33 is a cross-sectional view parallel to YZ plane showing the manufacturing process of the semiconductor device of the first example of the first embodiment.

FIG. 34 is a cross-sectional view parallel to ZX plane showing the manufacturing process of the semiconductor device of the first example of the first embodiment.

FIG. 35 is a cross-sectional view parallel to YZ plane showing the manufacturing process of the semiconductor device of the first example of the first embodiment.

FIG. 36 is a cross-sectional view parallel to ZX plane showing the manufacturing process of the semiconductor device of the first example of the first embodiment.

FIG. 37 is a cross-sectional view parallel to YZ plane showing the manufacturing process of the semiconductor device of the first example of the first embodiment.

FIG. 38 is a cross-sectional view parallel to ZX plane showing the manufacturing process of the semiconductor device of the first example of the first embodiment.

FIG. 39 is a cross-sectional view parallel to YZ plane showing the manufacturing process of the semiconductor device of the first example of the first embodiment.

FIG. 40 is a cross-sectional view parallel to ZX plane showing the manufacturing process of the semiconductor device of the first example of the first embodiment.

FIG. 41 is a cross-sectional view parallel to YZ plane showing the manufacturing process of the semiconductor device of the first example of the first embodiment.

FIG. 42 is a cross-sectional schematic view for illustrating a cross-sectional view parallel to ZX plane of a semiconductor device of a second example of the first embodiment.

FIG. 43 is a cross-sectional schematic view for illustrating a cross-sectional view parallel to YZ plane of the semiconductor device of the second example of the first embodiment.

FIG. 44 is a cross-sectional view parallel to ZX plane showing a manufacturing process of the semiconductor device of the second example of the first embodiment.

FIG. 45 is a cross-sectional view parallel to YZ plane showing the manufacturing process of the semiconductor device of the second example of the first embodiment.

FIG. 46 is a cross-sectional schematic view for illustrating a cross-sectional view parallel to ZX plane of a semiconductor device of a third example of the first embodiment.

FIG. 47 is a cross-sectional schematic view for illustrating a cross-sectional view parallel to YZ plane of the semiconductor device of the third example of the first embodiment.

FIG. 48 is a cross-sectional view parallel to ZX plane showing a manufacturing process of the semiconductor device of the third example of the first embodiment.

FIG. 49 is a cross-sectional view parallel to YZ plane showing the manufacturing process of the semiconductor device of the third example of the first embodiment.

FIG. 50 is a cross-sectional schematic view for illustrating a cross-sectional view parallel to ZX plane of a semiconductor device of a fourth example of the first embodiment.

FIG. 51 is a cross-sectional schematic view for illustrating a cross-sectional view parallel to YZ plane of the semiconductor device of the fourth example of the first embodiment.

FIG. 52 is a cross-sectional view parallel to ZX plane showing a manufacturing process of the semiconductor device of the fourth example of the first embodiment.

FIG. 53 is a cross-sectional view parallel to YZ plane showing the manufacturing process of the semiconductor device of the fourth example of the first embodiment.

FIG. 54 is a cross-sectional schematic view for illustrating a cross-sectional view parallel to ZX plane of a semiconductor device of a fifth example of the first embodiment.

FIG. 55 is a cross-sectional schematic view for illustrating a cross-sectional view parallel to YZ plane of the semiconductor device of the fifth example of the first embodiment.

FIG. 56 is a cross-sectional schematic view for illustrating a cross-sectional view parallel to ZX plane of a semiconductor device of a sixth example of the first embodiment.

FIG. 57 is a cross-sectional schematic view for illustrating a cross-sectional view parallel to YZ plane of the semiconductor device of the sixth example of the first embodiment.

FIG. 58 is a cross-sectional schematic view for illustrating a cross-sectional view parallel to ZX plane of a semiconductor device of a seventh example of the first embodiment.

FIG. 59 is a cross-sectional schematic view for illustrating a cross-sectional view parallel to YZ plane of the semiconductor device of the seventh example of the first embodiment.

FIG. 60 is a cross-sectional view parallel to ZX plane showing a manufacturing process of the semiconductor device of the seventh example of the first embodiment.

FIG. 61 is a cross-sectional view parallel to YZ plane showing the manufacturing process of the semiconductor device of the seventh example of the first embodiment.

FIG. 62 is a cross-sectional view parallel to ZX plane showing the manufacturing process of the semiconductor device of the seventh example of the first embodiment.

FIG. 63 is a cross-sectional view parallel to YZ plane showing the manufacturing process of the semiconductor device of the seventh example of the first embodiment.

FIG. 64 is a cross-sectional schematic view for illustrating a cross-sectional view parallel to ZX plane of a semiconductor device of an eighth example of the first embodiment.

FIG. 65 is a cross-sectional schematic view for illustrating a cross-sectional view parallel to YZ plane of the semiconductor device of the eighth example of the first embodiment.

FIG. 66 is a cross-sectional schematic view for illustrating a cross-sectional view parallel to ZX plane of a semiconductor device of a ninth example of the first embodiment.

FIG. 67 is a cross-sectional schematic view for illustrating a cross-sectional view parallel to YZ plane of the semiconductor device of the ninth example of the first embodiment.

FIG. 68 is a cross-sectional schematic view for illustrating a semiconductor device according to a second embodiment showing a cross-sectional view parallel to ZX plane.

FIG. 69 is a cross-sectional schematic view for illustrating the semiconductor device according to the second embodiment showing a cross-sectional view parallel to YZ plane.

FIG. 70 is a cross-sectional view parallel to ZX plane showing a manufacturing process of the semiconductor device according to the second embodiment.

FIG. 71 is a cross-sectional view parallel to YZ plane showing the manufacturing process of the semiconductor device according to the second embodiment.

FIG. 72 is a cross-sectional view parallel to ZX plane showing the manufacturing process of the semiconductor device according to the second embodiment.

FIG. 73 is a cross-sectional view parallel to YZ plane showing the manufacturing process of the semiconductor device according to the second embodiment.

FIG. 74 is a cross-sectional view parallel to ZX plane showing the manufacturing process of the semiconductor device according to the second embodiment.

FIG. 75 is a cross-sectional view parallel to YZ plane showing the manufacturing process of the semiconductor device according to the second embodiment.

FIG. 76 is a cross-sectional view parallel to ZX plane showing the manufacturing process of the semiconductor device according to the second embodiment.

FIG. 77 is a cross-sectional view parallel to YZ plane showing the manufacturing process of the semiconductor device according to the second embodiment.

FIG. 78 is a cross-sectional view parallel to ZX plane showing the manufacturing process of the semiconductor device according to the second embodiment.

FIG. 79 is a cross-sectional view parallel to YZ plane showing the manufacturing process of the semiconductor device according to the second embodiment.

FIG. 80 is a cross-sectional view parallel to ZX plane showing the manufacturing process of the semiconductor device according to the second embodiment.

FIG. 81 is a cross-sectional view parallel to YZ plane showing the manufacturing process of the semiconductor device according to the second embodiment.

FIG. 82 is a cross-sectional view parallel to ZX plane showing the manufacturing process of the semiconductor device according to the second embodiment.

FIG. 83 is a cross-sectional view parallel to YZ plane showing the manufacturing process of the semiconductor device according to the second embodiment.

FIG. 84 is a cross-sectional view parallel to ZX plane showing the manufacturing process of the semiconductor device according to the second embodiment.

FIG. 85 is a cross-sectional view parallel to YZ plane showing the manufacturing process of the semiconductor device according to the second embodiment.

FIG. 86 is a cross-sectional view parallel to ZX plane showing the manufacturing process of the semiconductor device according to the second embodiment.

FIG. 87 is a cross-sectional view parallel to YZ plane showing the manufacturing process of the semiconductor device according to the second embodiment.

FIG. 88 is a cross-sectional view parallel to ZX plane showing the manufacturing process of the semiconductor device according to the second embodiment.

FIG. 89 is a cross-sectional view parallel to YZ plane showing the manufacturing process of the semiconductor device according to the second embodiment.

FIG. 90 is a cross-sectional view parallel to ZX plane showing the manufacturing process of the semiconductor device according to the second embodiment.

FIG. 91 is a cross-sectional view parallel to YZ plane showing the manufacturing process of the semiconductor device according to the second embodiment.

FIG. 92 is a cross-sectional view parallel to ZX plane showing the manufacturing process of the semiconductor device according to the second embodiment.

FIG. 93 is a cross-sectional view parallel to YZ plane showing the manufacturing process of the semiconductor device according to the second embodiment.

FIG. 94 is a cross-sectional view parallel to ZX plane showing the manufacturing process of the semiconductor device according to the second embodiment.

FIG. 95 is a cross-sectional view parallel to YZ plane showing the manufacturing process of the semiconductor device according to the second embodiment.

FIG. 96 is a cross-sectional view parallel to ZX plane showing the manufacturing process of the semiconductor device according to the second embodiment.

FIG. 97 is a cross-sectional view parallel to YZ plane showing the manufacturing process of the semiconductor device according to the second embodiment.

FIG. 98 is a cross-sectional view parallel to ZX plane showing the manufacturing process of the semiconductor device according to the second embodiment.

FIG. 99 is a cross-sectional view parallel to YZ plane showing the manufacturing process of the semiconductor device according to the second embodiment.

### DETAILED DESCRIPTION

In general, according to one embodiment, a semiconductor device includes an oxide semiconductor column that extends in a first direction, a first electrode contacting a first end of the oxide semiconductor column; a second electrode contacting a second end of the oxide semiconductor column; a gate electrode that surrounds a portion of the oxide semiconductor column between the first end and the second end of the oxide semiconductor column; a first insulating film between the gate electrode and the oxide semiconductor column; and a second insulating film between the gate electrode and the first electrode in the first direction and surrounding the oxide semiconductor column via the first insulating film. There is a region in which at least a part of the oxide semiconductor column is accommodated that is formed by the gate electrode and the second insulating film. The region has a stepped surface facing towards the second electrode.

According to another embodiment, a semiconductor device includes a plurality of oxide semiconductor columns that each extend in a first direction and are spaced from each other in a second direction intersecting the first direction; a plurality of first electrodes respectively contacting first ends of the plurality of the oxide semiconductor columns; a plurality of second electrodes respectively contacting second ends of the plurality of the oxide semiconductor columns; a gate electrode extending along the second direction and surrounding the oxide semiconductor columns; a first insulating film between the gate electrode and each of the oxide semiconductor columns respectively; a fourth insulating film between the gate electrode and the plurality of second electrodes; and a fifth insulating film between adjacent oxide semiconductor columns in the second direction and below the fourth insulating film in the first direction. The fifth insulating film has a composition different from the fourth insulating film. The composition difference may be apparent based on differences in etch rates of the materials under similar etch conditions.

According to another embodiment, a semiconductor memory device includes: a semiconductor device such as one of those described above; a first capacitor electrode connected to the first electrode or the second electrode; a second capacitor electrode opposing the first capacitor electrode; and a dielectric film provided between the first capacitor electrode and the second capacitor electrode.

Hereinafter, certain example embodiments of the present disclosure will be described with reference to the accompanying drawings. For ease of understanding of the description, the same components are denoted by the same reference symbols in the drawings, and duplicate descriptions may be omitted.

### First Embodiment

A configuration of the semiconductor memory device according to the first embodiment will be described. X, Y and Z axes may be shown in each drawing. The X, Y and Z axes form three-dimensional orthogonal coordinates of a right-handed system. It is noted that the +Z-axis direction and the −Z-axis direction may be referred to for descriptive convenience using such terms as “upward,” “above” or “downward” “below,” or the like. The Z-axis direction may be referred to as “up and down” direction. “Above”, “below”, “up and down direction,” and the like are terms that indicate relative positional relationships in the drawings only, and do not define any orientation with respect to gravity direction. Planes orthogonal to the X, Y and Z axes may be referred to as YZ, ZX and XY planes, respectively.

Unless otherwise specifically stated, the dimensions or the like of components shown in the drawings may differ from the actual dimensions in order to facilitate understanding of the disclosure or the like.

As used herein, “connection” includes not only physical connection but also electrical connection, and includes not only direct connection but also indirect connection unless otherwise specified.

As used herein, “formed above” includes not only the case of being formed in contact above, but also the case of being formed above via other objects, unless otherwise specified. The same applies to the case of “formed below” and the like.

A semiconductor memory device 101 according to the first embodiment is an OS-RAM (Oxide Semiconductor-Random Access Memory), and includes a memory cell array.

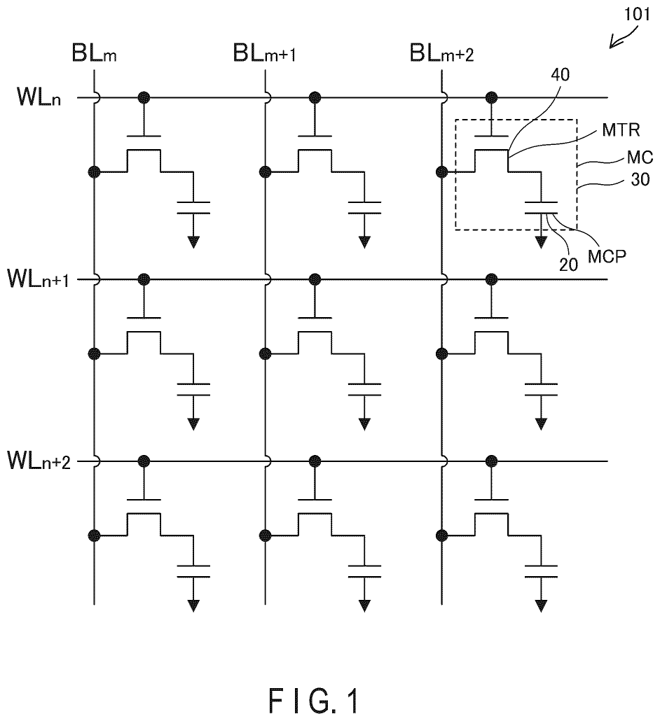

As shown in FIG. 1, the memory cell array includes a plurality of memory cells MC, a plurality of word lines WL, and a plurality of bit lines BL.

FIG. 1 shows a word line WLₙ, a word line WLₙ₊₁ and a word line WLₙ₊₂ as examples of multiple word lines WL (where n is a positive integer). FIG. 1 also shows a bit line BLₘ, a bit line BLₘ₊₁, and a bit line BLₘ₊₂ as examples of bit lines BL (where m is a positive integer). Note that the number of the plurality of memory cells MC is not limited to the number shown in FIG. 1.

A plurality of memory cells MC are arranged, for example, in a matrix to form a memory cell array. Each memory cell MC includes a memory transistor MTR, which is a field effect transistor (FET), and a memory capacitor MCP.

A series of memory cells MC provided along the row direction are connected to the same word line WL (for example, word line WLₙ) corresponding to rows to which they belong (for example, n-th row), respectively. A series of memory cells MC provided along the column direction are connected to the same bit line BL (for example, bit line Lₘ₊₂) corresponding to columns to which they belong (for example, M+2th column), respectively.

The gate of the memory transistor MTR included in the memory cell MC is connected to the word line WL corresponding to the row to which this memory cell MC belongs. One of the source and drain of the memory transistor MTR is connected to the bit line BL corresponding to the column to which this memory cell MC belongs.

One of the electrodes of the memory capacitor MCP included in the memory cell MC is connected to the other of the source and drain of the memory transistor MTR included in the memory cell MC. The other electrode of the memory cell MC is connected to a power line that supplies a specific potential.

The memory cell MC is configured to be able to retain data by switching the memory transistor MTR based on the potential on the corresponding word line WL to store charges in the memory capacitor MCP by the current flowing through the corresponding bit line BL.

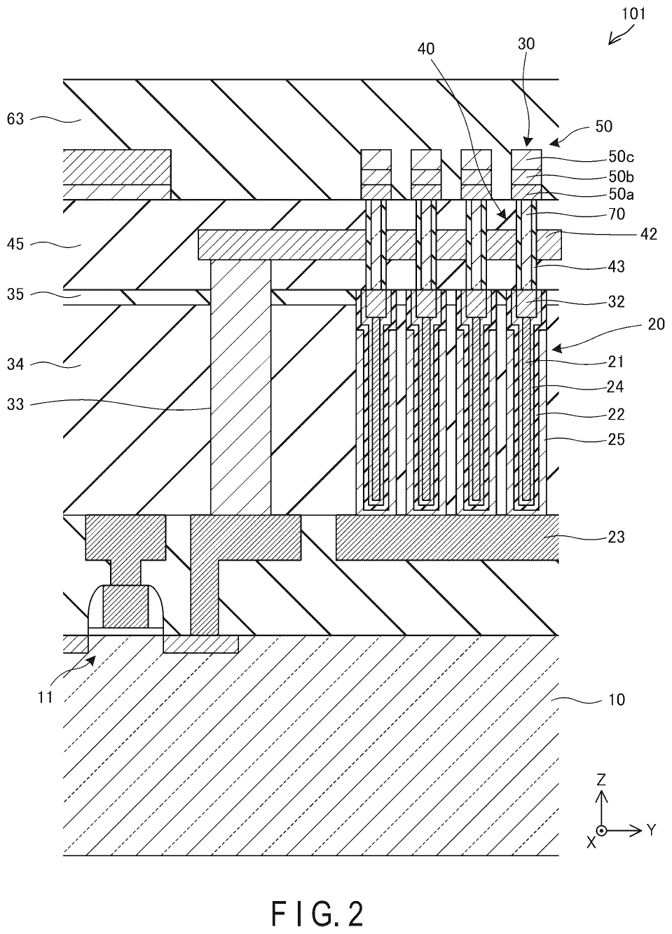

As shown in FIG. 2, the semiconductor memory device 101 includes a semiconductor substrate 10, a circuit 11, a capacitor 20, a semiconductor device 30, a conductor 33, and insulating layers 34, 35, 45 and 63.

The capacitor 20 includes a conductor 21, an insulating film 22 (an example of a “dielectric film”), a conductor 23, a capacitor electrode 24 (an example of a “first capacitor electrode”) and a capacitor electrode 25 (an example of a “second capacitor electrode”).

The semiconductor device 30 includes a field effect transistor 40 (an example of a “semiconductor element”), an upper electrode 50 (an example of a “first electrode”) provided above the field effect transistor 40, and a lower electrode 32 (an example of a “second electrode”) provided below the field effect transistor 40.

The field effect transistor 40 includes an oxide semiconductor layer 70 (an example of an “oxide semiconductor column”) corresponding to a channel, a gate insulating film 43 (an example of a “first insulating film”), and a conductive layer 42 (an example of a “gate electrode”).

The oxide semiconductor layer 70 is formed in an insulating layer 45, and has an upper end 70a (an example of “first end”) and a lower end 70b (an example of a “second end”). The oxide semiconductor layer 70 is a columnar body that extends in the +Z-axis direction (an example of “first direction”) which is from the lower end 70b to the upper end 70a. The oxide semiconductor layer 70 forms the channel of the field effect transistor 40, and the oxide semiconductor layer 70 has an amorphous structure.

The conductive layer 42 functions as the gate electrode of the field effect transistor 40 and surrounds the oxide semiconductor layer 70 via the gate insulating film 43 between the upper end 70a and the lower end 70b of the oxide semiconductor layer 70. The conductive layer 42 comprises, for example, tungsten.

The gate insulating film 43 can be, for example, a silicon nitride film (Si₃N₄).

The upper electrode 50 is formed in the +Z-axis direction from the oxide semiconductor layer 70, and contacts with the upper end 70a of the oxide semiconductor layer 70. The upper electrode 50 includes a metal oxide layer 50a, a barrier metal layer 50b, and a metal film 50c.

The metal film 50c comprises tungsten (W). The metal oxide layer 50a is formed between the metal film 50c and the upper end 70a of the oxide semiconductor layer 70 and comprises metal oxide. The metal oxide comprises, for example, indium and tin as metallic elements. In the present embodiment, the metal oxide layer 50a is indium-tin-oxide (ITO).

The barrier metal layer 50b comprises titanium and nitrogen and is formed between the metal oxide layer 50a and the metal film 50c. In the present embodiment, the barrier metal layer 50b is, for example, titanium nitride (TiN).

The lower electrode 32 contacts with the lower end 70b of the oxide semiconductor layer 70. The lower electrode 32 can be, for example, an ITO layer, that is, a metal oxide layer such as indium-tin-oxide (ITO).

Note that the lower electrode 32 is not limited to an ITO material, and comprise at least one of the following elements: indium, tin, zinc, cadmium, gold, silver, platinum, lead, copper, nickel, tungsten, and iron.

The circuit 11 forms peripheral circuits including: a decoder for selecting a predetermined memory cell MC among a plurality of memory cells MC, (capacitors 20 and field effect transistors 40) of the semiconductor memory device 101; a sense amplifier connected to a bit line BL; and a register including an SRAM. The circuit 11 may include a CMOS circuit having field effect transistors formed in a CMOS process: a P-channel field effect transistor (Pch-FET) and an N-channel field effect transistor (Nch-FET).

Field effect transistors of the circuit 11 can be formed using a semiconductor substrate 10, such as a single crystal silicon substrate. The Pch-FET and the Nch-FET are so-called lateral field effect transistors that have a channel region, a source region, and a drain region on the semiconductor substrate 10, and have a channel for carriers to flow in the X-axis direction or Y-axis direction which is substantially parallel to the surface of the semiconductor substrate 10 in a region close to the surface of the semiconductor substrate 10. Note that the semiconductor substrate 10 may have a conductivity type of P-type to N-type. Note that FIG. 2 illustrates an example of the field effect transistor of the circuit 11 for convenience.

The capacitor 20 is a memory capacitor MCP included in the memory cell MC (see FIG. 1). Although four capacitors 20 are illustrated in FIG. 2, the number of capacitors 20 is not limited to four.

In the present embodiment, the capacitor 20 is provided above the semiconductor substrate 10. The capacitor electrode 24 in the capacitor 20 is connected to the conductor 21 and the lower electrode 32. The capacitor electrode 25 opposes the capacitor electrode 24. The insulating film 22 is provided between the capacitor electrode 24 and the capacitor electrode 25.

The capacitor 20 can be a three-dimensional capacitor such as a pillar capacitor. Note that other capacitor designs providing a configuration capable of storing charges may be employed as the capacitor in the present disclosure.

The conductor 21 is in contact with the lower end face of the lower electrode 32 and extends downward from this end. The capacitor electrode 24 is formed to cover the lower electrode 32 and the conductor 21. The insulating film 22 is formed to cover the capacitor electrode 24. The capacitor electrode 25 has a lower end that surrounds a part of the lower portion of the insulating film 22 and abuts on the upper end face of the conductor 23.

The conductor 21 may comprise a material such as amorphous silicon. The insulating film 22 may comprise a material such as hafnium oxide. The conductor 23 and the capacitor electrodes 24 and 25 may comprise materials such as tungsten (W) and/or titanium nitride (TiN).

The conductor 33 includes wiring that electrically connects the circuit 11 to the semiconductor device 30. The conductor 33 may include via wiring, for example, via wiring extending in the Z-axis direction as shown in FIG. 2 to connect word lines WL with the circuit 11 provided on the semiconductor substrate 10. The conductor 33 comprises, for example, copper.

The insulating layer 34 is provided between the plurality of capacitors 20 otherwise adjacent to each other. The insulating layer 34 is, for example, a silicon oxide film.

The insulating layer 35 is provided above the insulating layer 34. The insulating layer 35 is, for example, a silicon nitride film.

The semiconductor device 30 is provided above the capacitor 20. The field effect transistor 40 in the semiconductor device 30 can correspond to the memory transistor MTR of the memory cell MC (see FIG. 1).

In the semiconductor device 30, the field effect transistor 40 is provided above the lower electrode 32. Specifically, the oxide semiconductor layer 70 of the field effect transistor 40 is located in the direction going away from the semiconductor substrate 10, that is, an upward from the lower electrode 32.

The upper electrode 50 is located in the direction away from the semiconductor substrate 10 going upward from the oxide semiconductor layer 70. With this configuration, the field effect transistor 40 is a so-called vertical transistor with a channel extending in the Z-axis direction (up and down direction) which is substantially perpendicular to the surface of the semiconductor substrate 10.

The oxide semiconductor layer 70 is a semiconductor material in which oxygen deficiency is a donor. The oxide semiconductor layer 70 comprises indium (In), zinc (Zn), and/or gallium (Ga) as metallic elements. Specifically, the oxide semiconductor layer 70 can be an oxide of indium, gallium, and zinc, namely, IGZO (InGaZnO). Note that the oxide semiconductor layer 70 may be another type of oxide semiconductor in other examples.

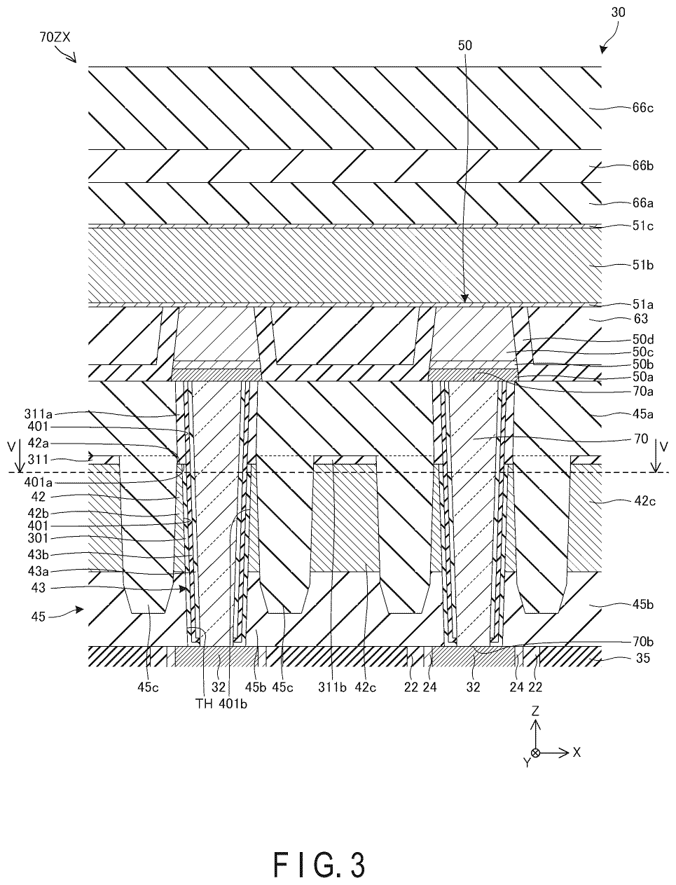

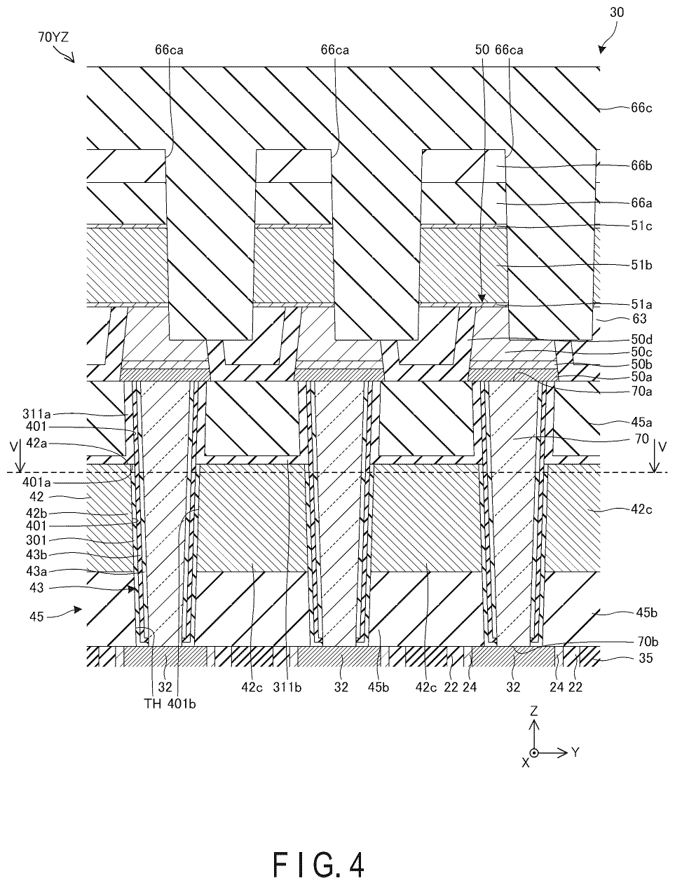

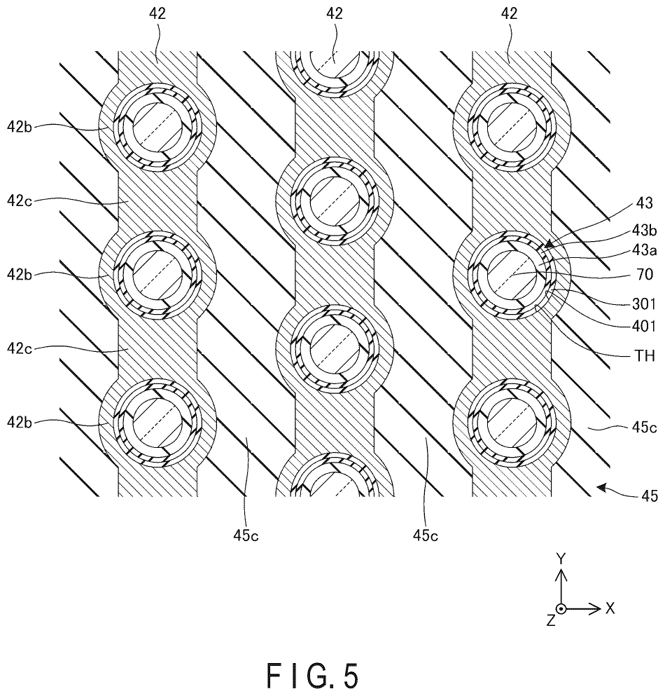

FIG. 3 shows a cross-sectional view of the semiconductor device 30 when viewed in a cross-section 70ZX parallel to ZX plane and included in the oxide semiconductor layer 70. FIG. 4 shows a cross-sectional view of the semiconductor device 30 when viewed in a cross-section 70YZ parallel to YZ plane and included in the oxide semiconductor layer 70. FIG. 5 is a cross-sectional view taken along cut line V-V shown in FIGS. 3 and 4.

The first example of the semiconductor device 30 according to the first embodiment (sometimes referred to as the first example of the first embodiment) will be described below.

### The First Example of the First Embodiment

As shown in FIGS. 3 to 5, in the first example of the first embodiment, the semiconductor device 30 further includes a liner film 301 (an example of a “third insulating film”) and a spacer film 311. The gate insulating film 43 includes insulating films 43a and 43b. The insulating layer 45 includes insulating films 45a, 45b and 45c.

A plurality of conductive layers 42 are repeatedly provided in the +X-axis direction (an example of a “third direction”). A plurality of oxide semiconductor layers 70 are arranged in a two-dimensional array. Therefore, some of the plurality of oxide semiconductor layers 70 are provided along the +Y-axis direction (an example of a “second direction”). Some others of the plurality of oxide semiconductor layers 70 are provided along the +X-axis direction.

The conductive layer 42 extends along the +Y-axis direction, and surrounds the plurality of oxide semiconductor layers 70 provided along the +Y-axis direction, respectively, via a plurality of gate insulating films 43.

Specifically, the conductive layer 42 includes surrounding portions 42b (an example of “first portions”) for surrounding the oxide semiconductor layers 70 and connecting portions 42c (an example of “second portions”) for connecting two surrounding portions 42b.

When the conductive layer 42 is viewed from above, the width in the X-axis direction of the connecting portion 42c is narrower than the width in the X-axis direction of the surrounding portion 42b.

The spacer film 311 (an example of a “second insulating film”) is provided on the +Z-axis direction side of the conductive layer 42. The spacer film 311 is, for example, an oxide of silicon. The spacer film 311 includes a cylindrical portion 311a and a plate-like portion 311b.

The cylindrical portion 311a is provided above the surrounding portion 42b in the conductive layer 42 and extends substantially parallel to the Z-axis. Specifically, the lower end of the cylindrical portion 311a is an annular surface in contact with an upper surface 42a of the conductive layer 42. Cylindrical portion 311a surrounds the oxide semiconductor layer 70 via the gate insulating film 43. The plate-like portion 311b is provided above the connecting portion 42c in the conductive layer 42, and extends substantially parallel to XY plane.

The insulating films 45a and 45b are provided above the plate-like portion 311b and below the conductive layer 42, respectively. The insulating film 45a and 45b are, for example, an oxide of silicon.

The insulating film 45c separates the two conductive layers 42 adjacent in the +X-axis direction. Specifically, the insulating film 45c is located between the two conductive layers 42 adjacent in the +X-axis direction, and extends substantially parallel to the Y-axis.

The upper end of the insulating film 45c is connected to the lower surface of the insulating film 45a. The lower part of the insulating film 45c is buried in the insulating film 45b. In the present embodiment, the insulating films 45a and 45c are integrally formed.

A region 401 (in which at least a part of the oxide semiconductor layer 70 is accommodated) is formed by the surrounding portion 42b of the conductive layer 42 and the cylindrical portion 311a of the spacer film 311. In the present embodiment, the region 401 accommodates a part of the upper portion of the oxide semiconductor layer 70. That is, the upper portion of the oxide semiconductor layer 70 is inside the region 401. Note that the region 401 may accommodate all of the oxide semiconductor layer 70 in some examples.

A stepped surface 401a facing in the −Z-axis direction is formed on an inner wall 401b of the region 401. The stepped surface 401a is located between the conductive layer 42 and the upper electrode 50. The stepped surface 401a is annular when viewed from below.

According to the present embodiment, in the region 401, since the inner diameter of the lower end of the cylindrical portion 311a is smaller than the inner diameter of the upper portion of the surrounding portion 42b, the stepped surface 401a is a portion of the lower end face of the cylindrical portion 311a near the center. The upper surface 42a of the conductive layer 42 meets the stepped surface 401a.

The gate insulating film 43 surrounds a part of the upper portion of the oxide semiconductor layer 70 over its entire circumference. The gate insulating film 43 has two layers: the insulating film 43a and 43b. The insulating film 43a is provided closer to the oxide semiconductor layers 70 than the insulating film 43b. The upper ends of the insulating films 43a and 43b contact with the metal oxide layer 50a. The insulating film 43a comprises, for example, an oxide of silicon (e.g., a silicon oxide). The insulating film 43b comprises, for example, a nitride of silicon (e.g., a silicon nitride).

The liner film 301 is located at least between the conductive layer 42 and insulating film 45b and the gate insulating film 43. The liner film 301 surrounds a part of the lower portion of the oxide semiconductor layer 70 from the outside of the gate insulating film 43 over the entire circumference. Specifically, the lower end of the liner film 301 contacts with the lower electrode 32. The upper end of the liner film 301 contacts with the stepped surface 401a of the region 401, that is, the lower end face of the cylindrical portion 311a.

The liner film 301 comprises, for example, at least one of the following elements: silicon, aluminum, zirconium, hafnium, lanthanum, titanium, and strontium, along with at least one of oxygen and nitrogen. In the present embodiment, the liner film 301 is silicon nitride. Note that the liner film 301 in other examples may be configured to comprises silicon oxide, silicon oxynitride, aluminum oxide, aluminum nitride, zirconium oxide, hafnium oxide, ruthenium oxide, niobium oxide, yttrium oxide, tantalum oxide, vanadium oxide, magnesium oxide, lanthanum oxide, titanium oxide, strontium oxide, or the like.

### Semiconductor Device Manufacturing Method

A method for manufacturing the semiconductor device 30 will be described as an example of a method for manufacturing the semiconductor device according to the first embodiment.

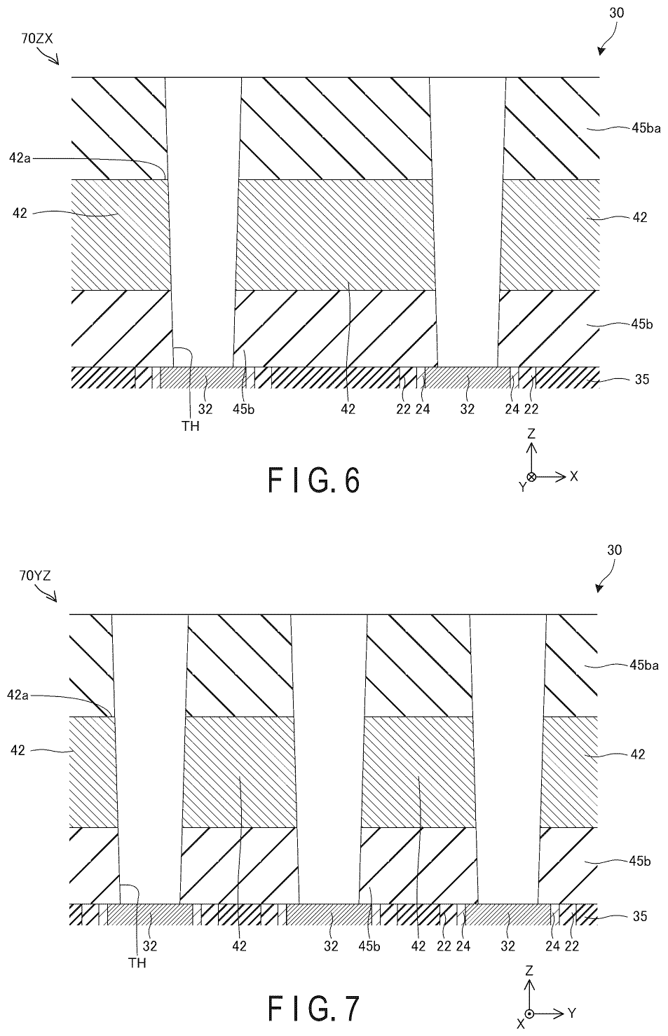

First, as shown in FIGS. 6 and 7, the insulating film 45b, the conductive layer 42, and the insulating film 45ba are provided above the insulating layer 35 in this order. The insulating film 45b, the conductive layer 42, and the insulating film 45ba extend substantially parallel to XY plane. A transistor hole TH is formed which extends substantially parallel to the Z-axis and penetrates through the insulating film 45ba, conductive layer 42 and insulating film 45b, and then the transistor hole TH is cleaned. At the bottom of the transistor hole TH, the lower electrode 32 is exposed.

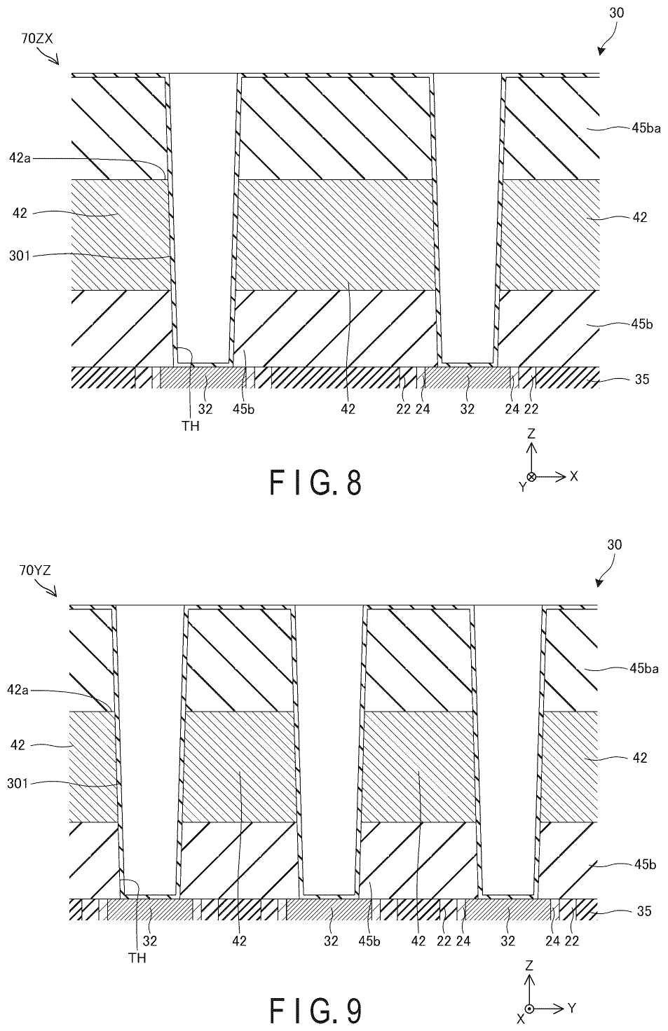

Then, as shown in FIGS. 8 and 9, for example, the liner film 301 with the thickness of 3 nm or more is formed above the semiconductor device 30 by atomic layer deposition. Thereby, the inner wall of the transistor hole TH is covered by the liner film 301, and the lower electrode 32 is not exposed.

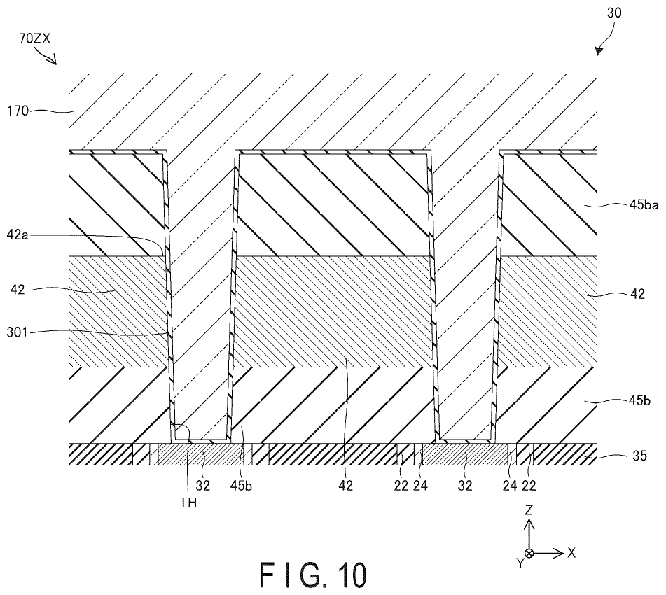

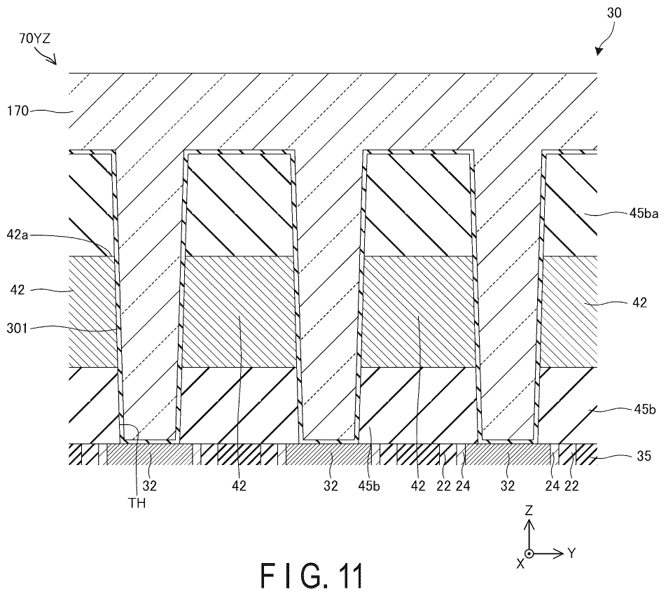

Then, as shown in FIGS. 10 and 11, a sacrificial amorphous silicon layer 170 is formed above the semiconductor device 30. Thereby, the transistor hole TH is filled with the sacrificial amorphous silicon layer 170.

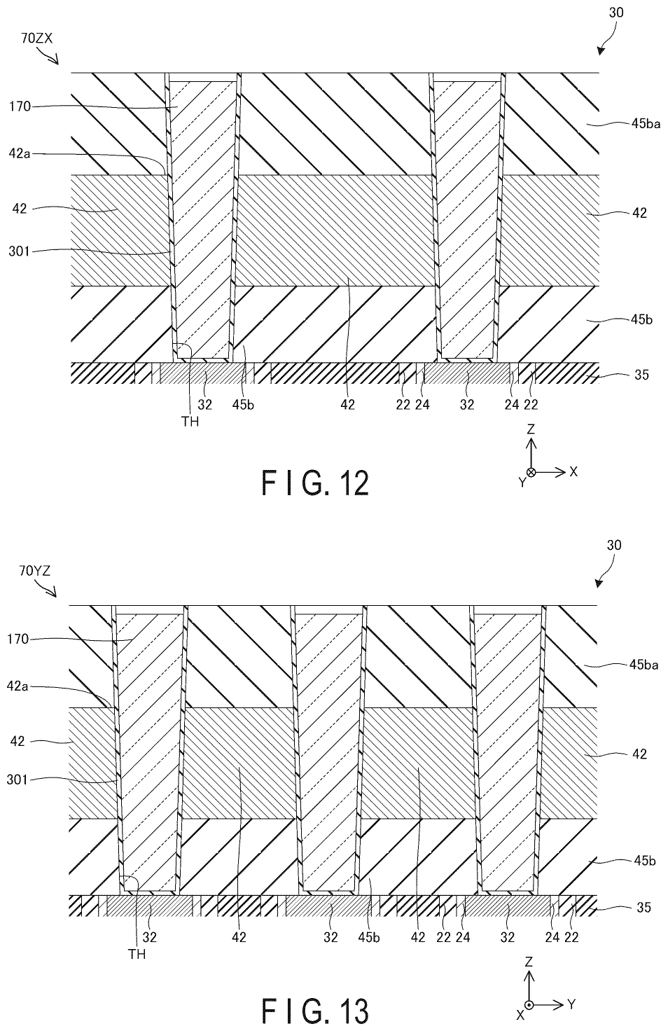

Then, as shown in FIGS. 12 and 13, the sacrificial amorphous silicon layer 170 is etched back, so that a part of the upper portion of the sacrificial amorphous silicon layer 170 is removed, and the upper surface of the insulating film 45ba is exposed. At this time, the upper end of the sacrificial amorphous silicon layer 170 is located above the conductive layer 42 inside the transistor hole TH, for example.

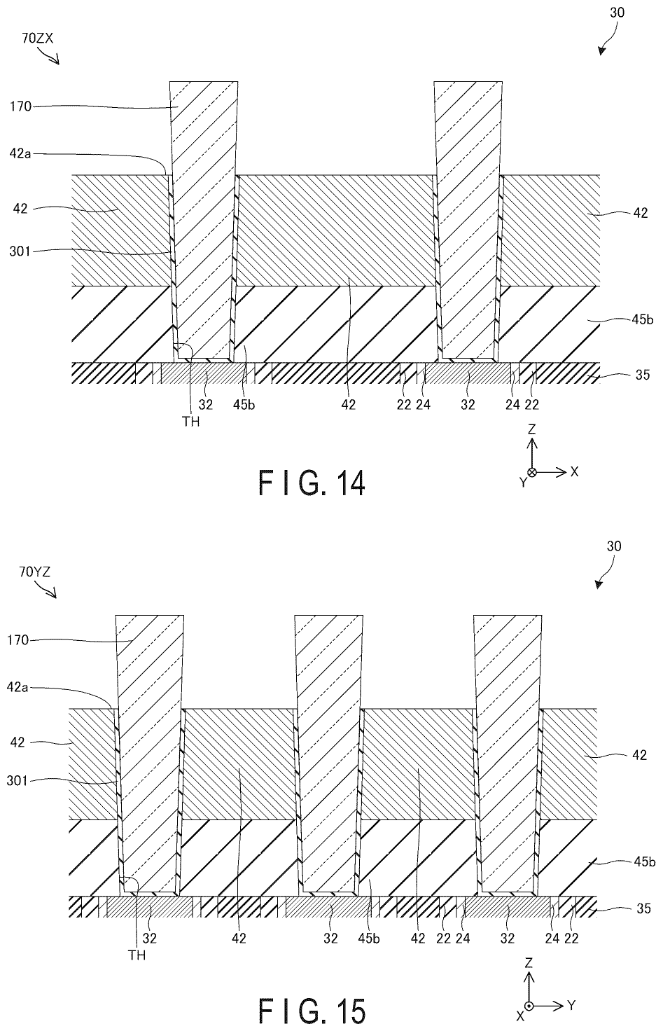

Then, as shown in FIGS. 14 and 15, the insulating film 45ba is removed by etching. Then, a portion of the liner film 301 exposed above the conductive layer 42 is removed by etching. Thereby, the upper surface 42a of the conductive layer 42 is aligned with the upper end of the liner film 301.

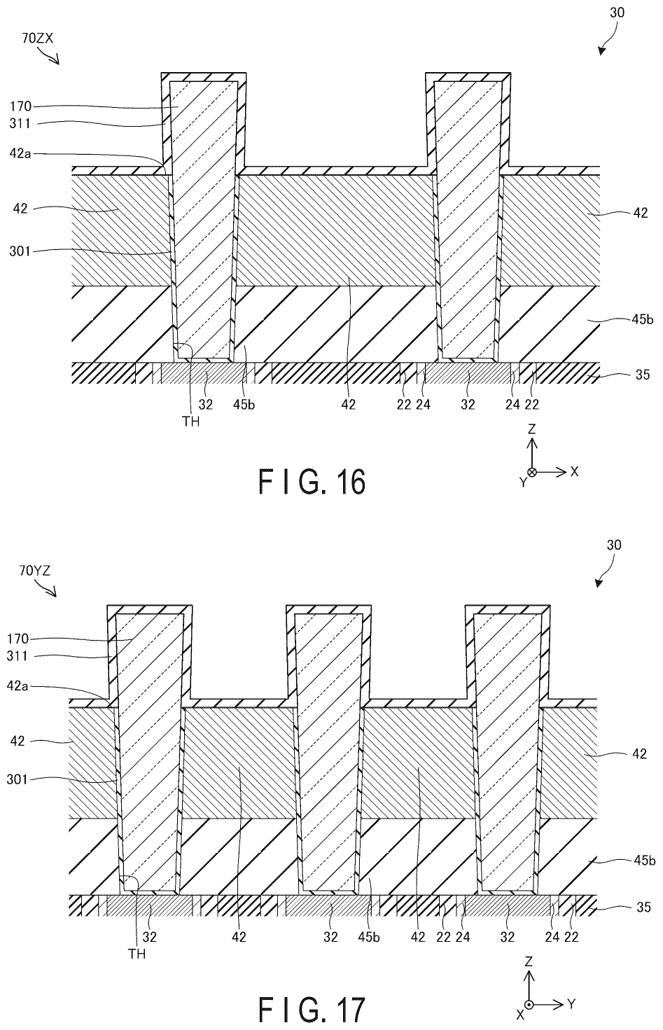

Then, as shown in FIGS. 16 and 17, the spacer film 311 is formed above the semiconductor device 30. Therefore, the spacer film 311 covers an exposed portion of the sacrificial amorphous silicon layer 170 above the conductive layer 42, and the upper surface 42a of the conductive layer 42.

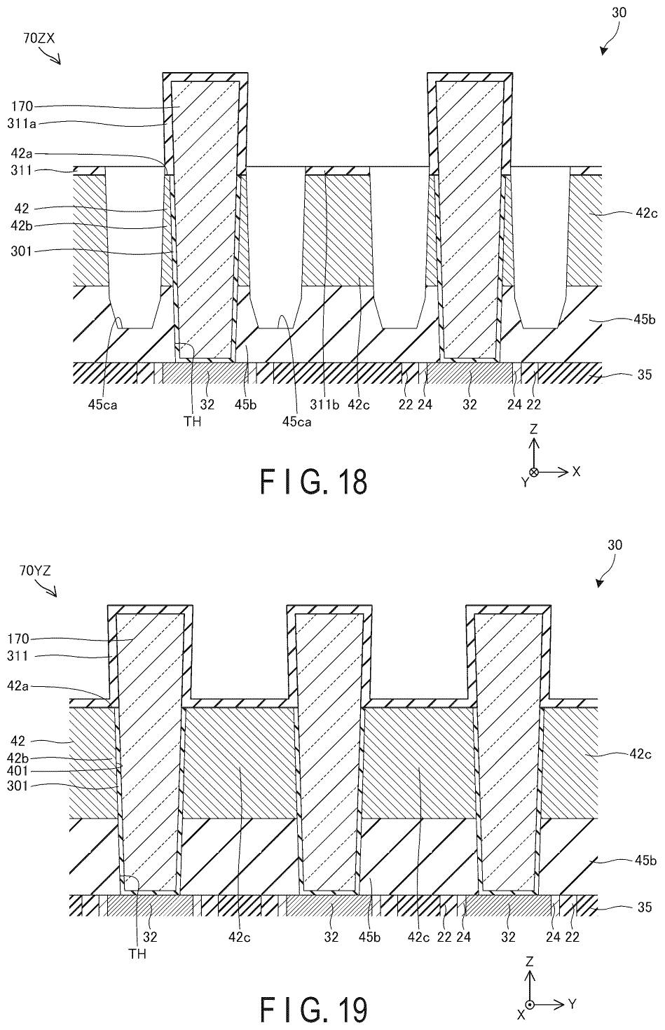

Next, as shown in FIGS. 18 and 19, after deposition, resist coating, exposure, development, peeling, and the like are performed by a lithography method on the surface of the semiconductor device 30 to form a mask, a groove 45ca, which penetrates to the insulating film 45b by etching and extends substantially parallel to the Y-axis, is formed in the semiconductor device 30. Thereby, the spacer film 311 is separated into the cylindrical portion 311a and the plate-like portion 311b. Further, the conductive layer 42 is separated into a plurality of electrodes which extend substantially parallel to the Y-axis and repeatedly provided in the +X-axis direction. These electrodes correspond to the word lines WL (see FIG. 1).

Note that the surrounding portions 42b of the conductive layer 42 are formed by a self-align-process. Specifically, even if the mask formation position in the lithography process is shifted, the cylindrical portion 311a of the spacer film 311 located on the side of the sacrificial amorphous silicon layer 170 still functions as a mask, so that the surrounding portions 42b are formed in a self-aligned manner around the transistor hole TH.

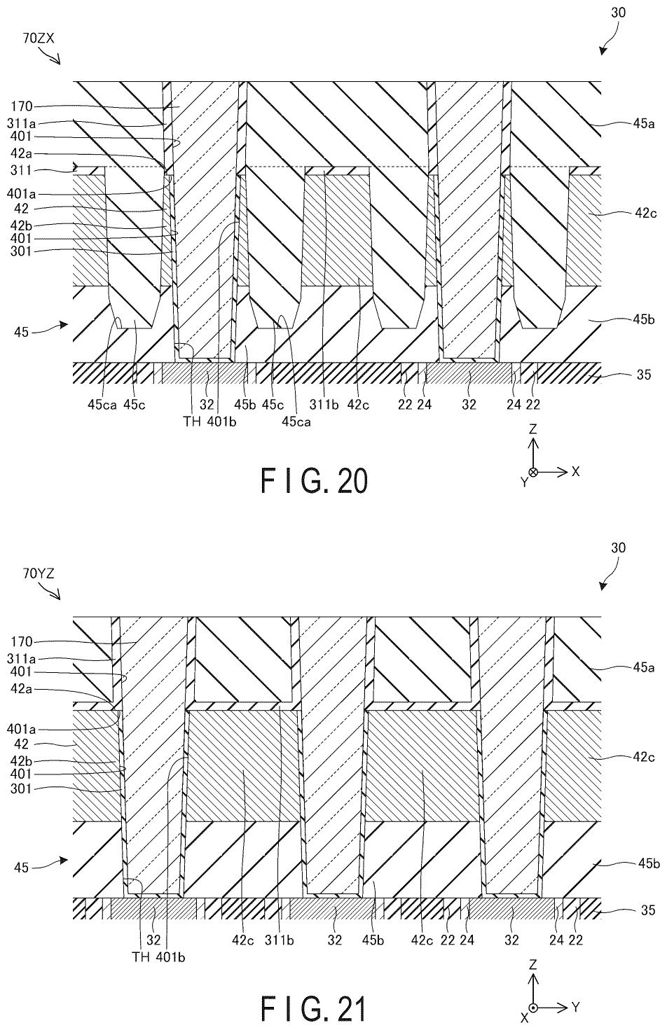

Then, as shown in FIGS. 20 and 21, the insulating films 45c and 45a are integrally formed above the semiconductor device 30. Then, the upper surface of the semiconductor device 30 is subjected to chemical mechanical polishing so that the upper surface of the sacrificial amorphous silicon layer 170 is exposed from the insulating film 45a.

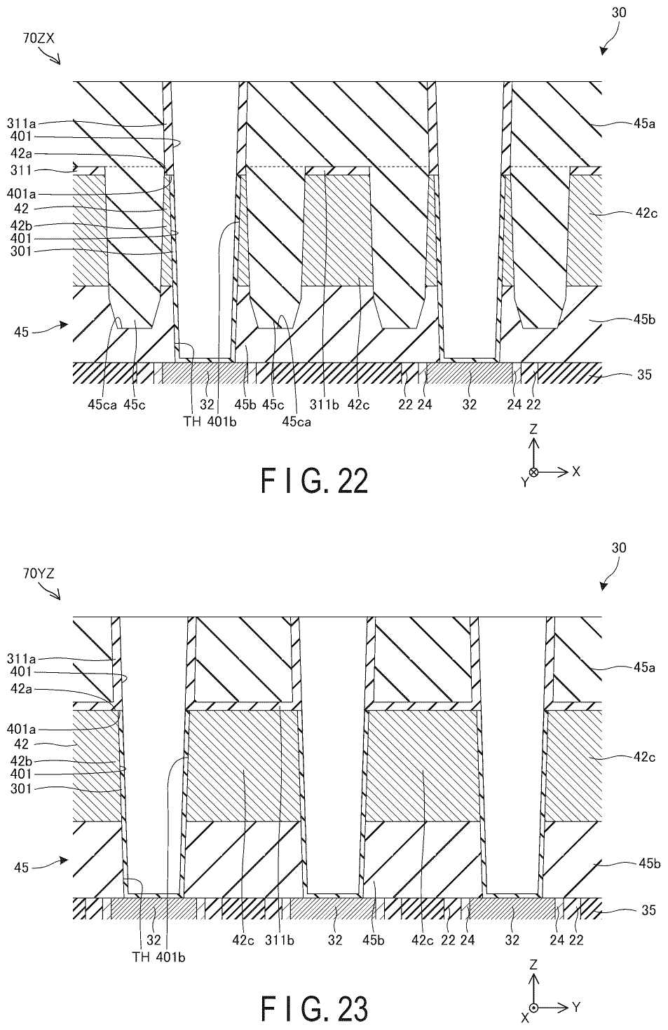

Then, as shown in FIGS. 22 and 23, the sacrificial amorphous silicon layer 170 within the transistor hole TH is removed by etching.

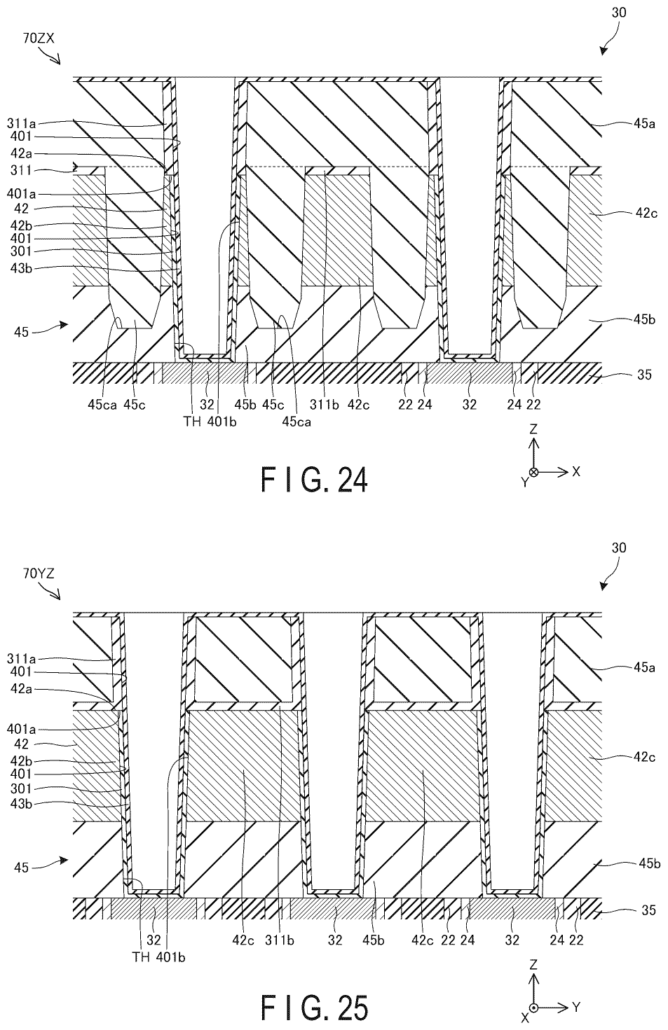

Then, as shown in FIGS. 24 and 25, the insulating film 43b is formed above the semiconductor device 30.

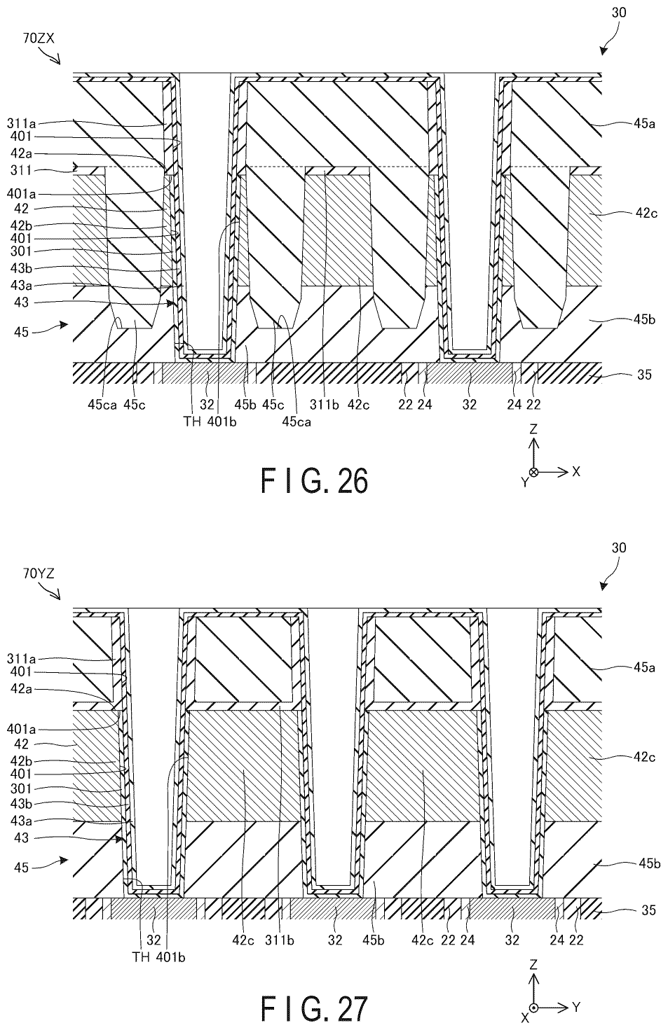

Then, as shown in FIGS. 26 and 27, the insulating film 43a is formed above the semiconductor device 30.

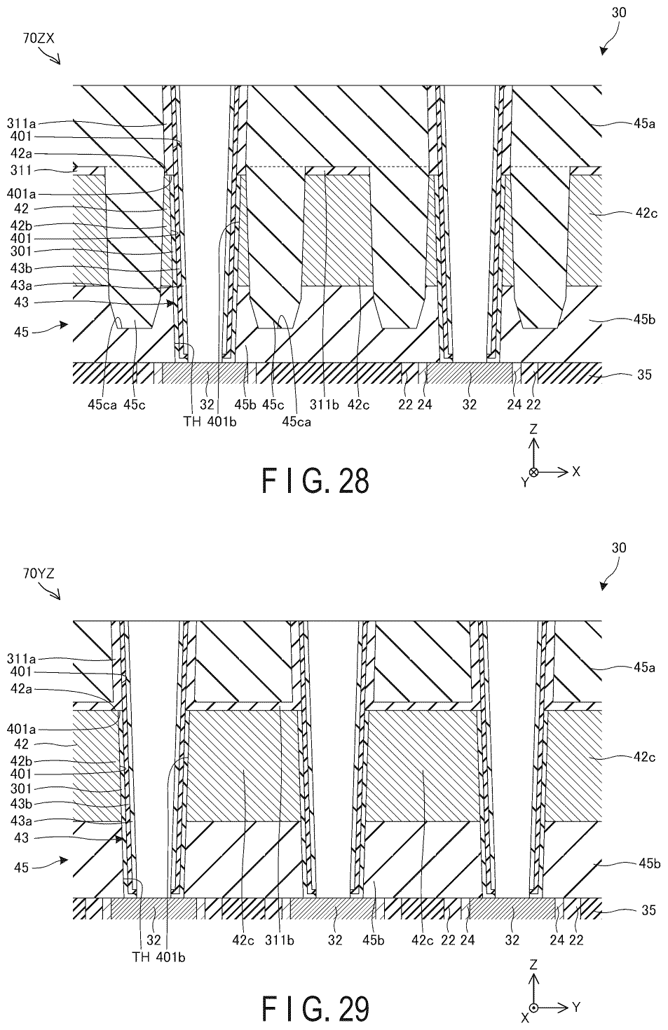

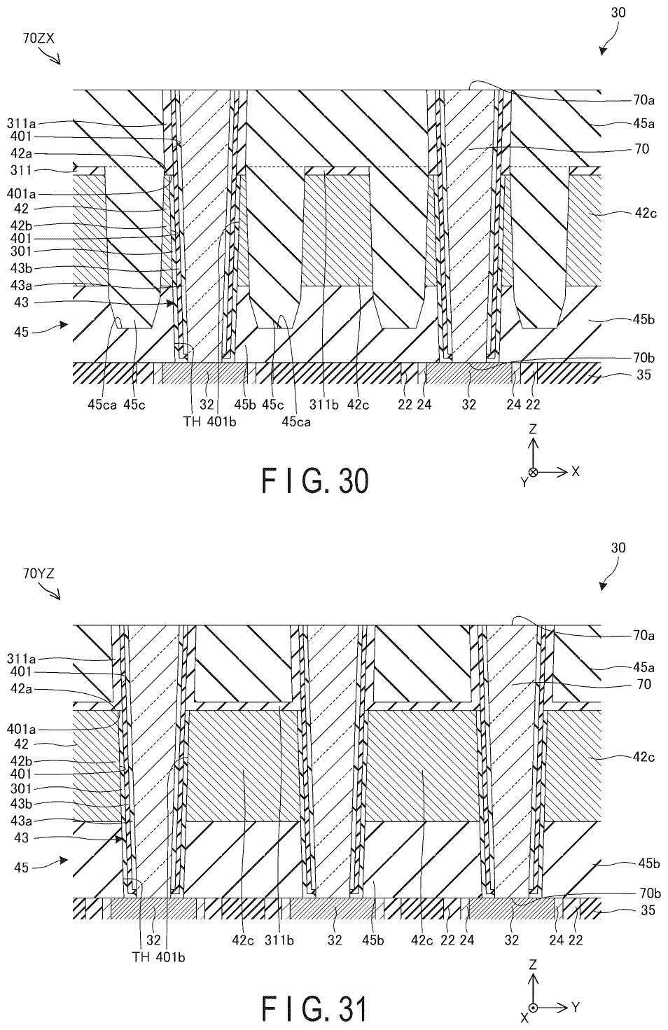

Then, as shown in FIGS. 28 and 29, the upper portion of the semiconductor device 30 is etched back by reactive ion etching so that the insulating film 45a is exposed, and further the lower electrode 32 is exposed on the bottom of the transistor hole TH.

Then, as shown in FIGS. 30 and 31, the oxide semiconductor layer 70 is formed inside the transistor hole TH. Then, the upper surface of the semiconductor device 30 is chemically mechanically polished.

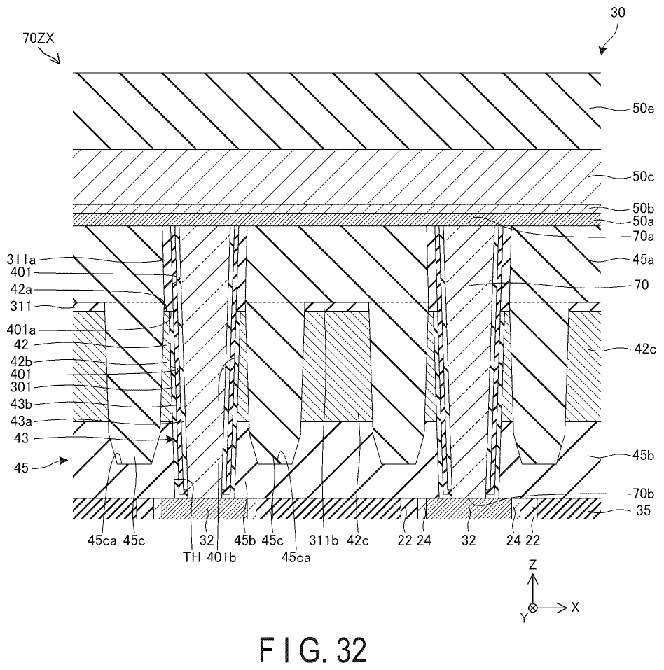

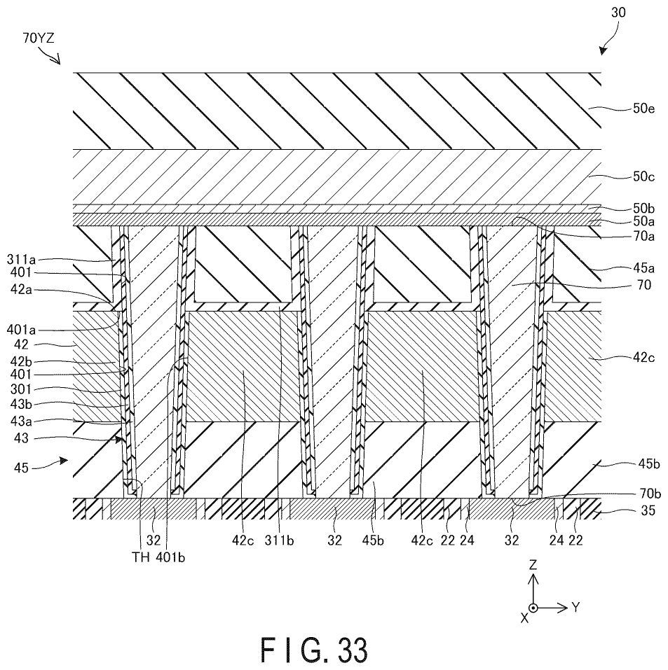

Then, as shown in FIGS. 32 and 33, on the upper surface of the semiconductor device 30, the metal oxide layer 50a, the barrier metal layer 50b, and the metal film 50c are formed from the bottom to the top. Then, an LPHM (Landing Pad Hard Mask) film 50e comprising, for example, an oxide of silicon is formed above the metal film 50c.

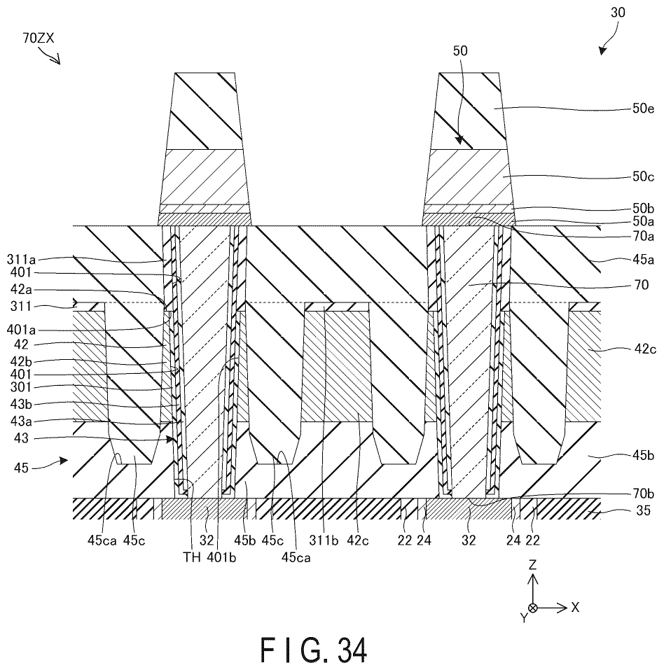

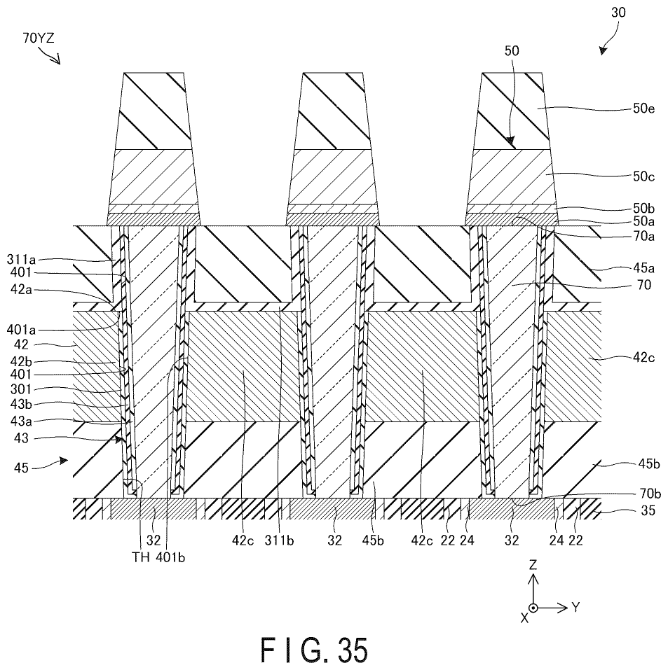

Next, as shown in FIGS. 34 and 35, after deposition, resist coating, exposure, development, peeling, and the like are performed by a lithography method on the surface of the semiconductor device 30 to form a mask, the upper electrode 50, which functions as a landing pad, is formed on the semiconductor device 30 by etching. The upper electrode 50 includes a barrier metal layer 51a, a barrier metal layer 50b, and a metal film 50c.

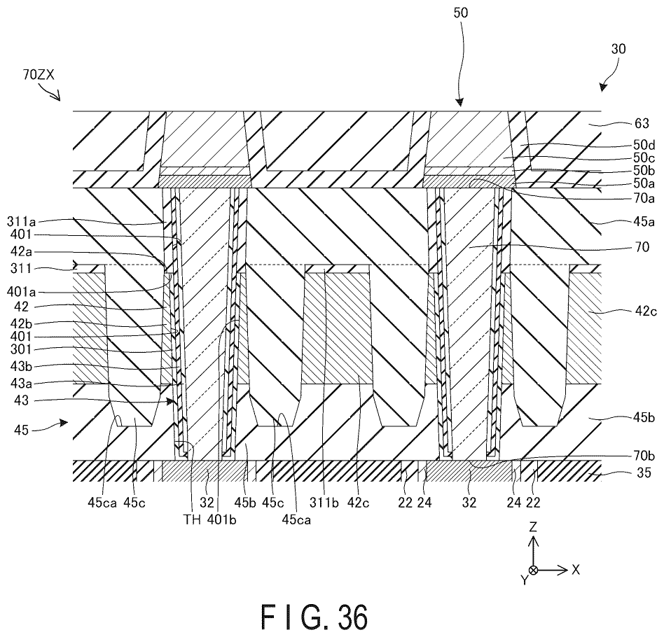

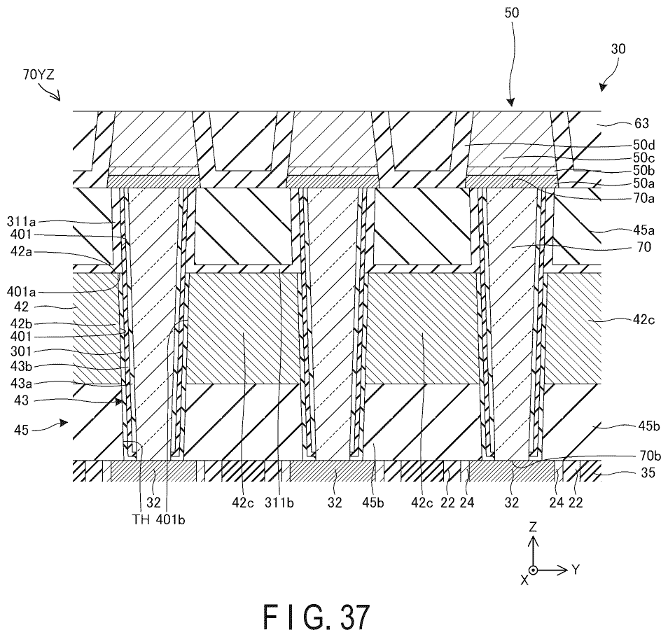

Then, as shown in FIGS. 36 and 37, an LP liner film 50d comprising, for example, silicon oxide is formed on the upper surface of the semiconductor device 30. Above the LP liner film 50d, an insulating layer 63 is formed which fills the gap formed by the LP liner film 50d. The insulating layer 63 comprises, for example, silicon oxide. Then, the upper surface of the semiconductor device 30 is chemically mechanically polished.

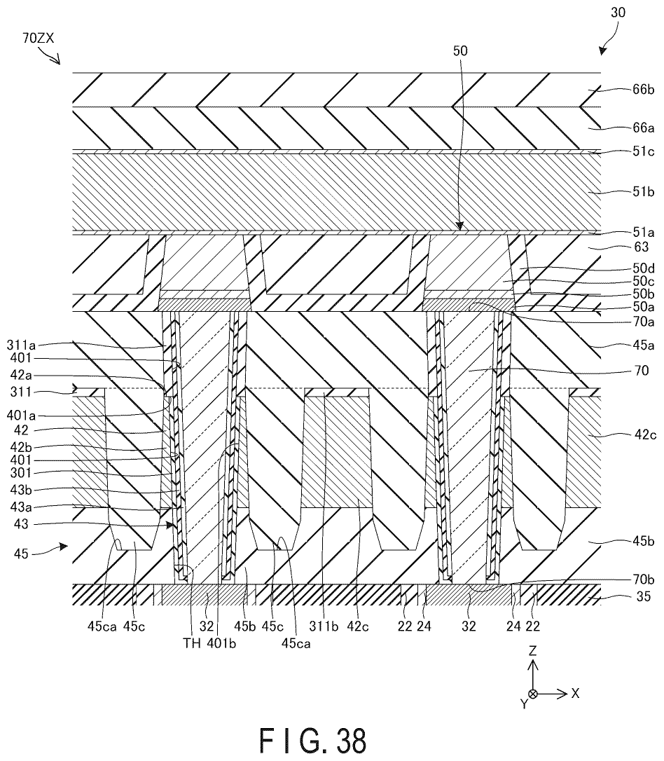

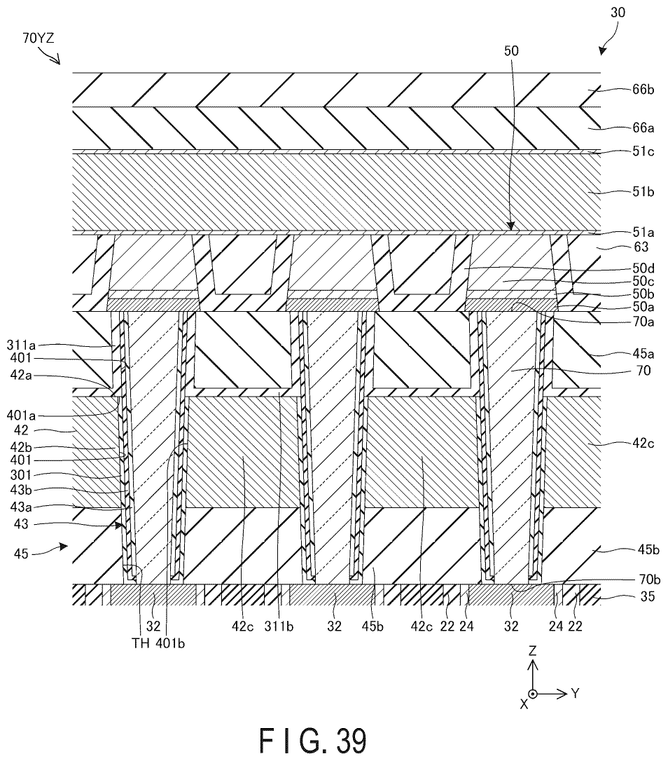

Then, as shown in FIGS. 38 and 39, on the upper surface of the semiconductor device 30, the barrier metal layer 51a, the conductive layer 51b, and the barrier metal layer 51c are formed from the bottom to the top. The barrier metal layers 51a and 51c comprise, for example, titanium nitride. The conductive layer 51b comprises, for example, tungsten.

Then, on the upper surface of the barrier metal layers 51c, BLHM (Bit Line Hard Mask) films 66a and 66b are formed from the bottom to the top. The BLHM films 66a and 66b comprise, for example, silicon nitride and silicon oxide, respectively.

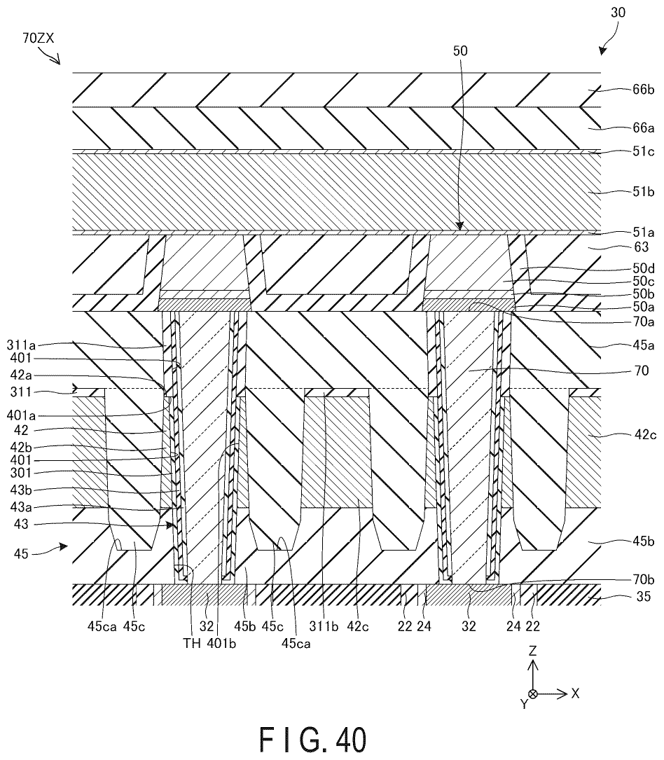

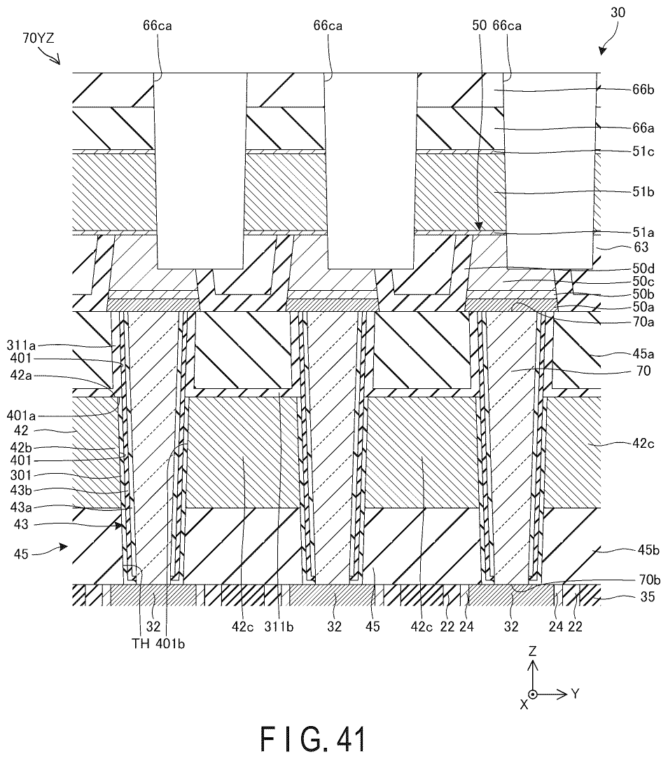

Next, as shown in FIGS. 40 and 41, after deposition, resist coating, exposure, development, peeling, and the like are performed by a lithography method on the surface of the semiconductor device 30 to form a mask, a groove 66ca, which penetrates to the insulating layer 63 and the metal film 50c by etching and extends substantially parallel to the X-axis, is formed in the semiconductor device 30. Thereby, the barrier metal layer 51a, the conductive layer 51b, and the barrier metal layer 51c are separated into electrodes which extend substantially parallel to the X-axis and repeatedly provided in the +Y-axis direction. These electrodes correspond to the bit lines BL (see FIG. 1).

Then, as shown in FIGS. 3 and 4, above the semiconductor device 30, the insulating film 66c is formed which fills the groove 66ca. The insulating film 66c comprises, for example, silicon oxide.

### Effect

In a case where the liner film 301 is not formed, when the sacrificial amorphous silicon layer 170 is formed above the semiconductor device 30 under a reducing atmosphere, the sacrificial amorphous silicon layer 170 is formed directly on the lower electrode 32 comprising ITO. At this time, silicon whiskers may be generated at the contact portion between the lower electrode 32 and the sacrificial amorphous silicon layer 170.

In contrast, according to the present embodiment, as shown in FIGS. 10 and 11, when the sacrificial amorphous silicon layer 170 is formed, the inner wall of the transistor hole TH is covered by the liner film 301 so that the lower electrode 32 is not exposed. This can prevent contact between the lower electrode 32 and the sacrificial amorphous silicon layer 170, thereby suppressing the generation of silicon whiskers.

Next, a second example of the semiconductor device 30 according to the first embodiment (sometimes referred to as the second example of the first embodiment) will be described.

### The Second Example of the First Embodiment

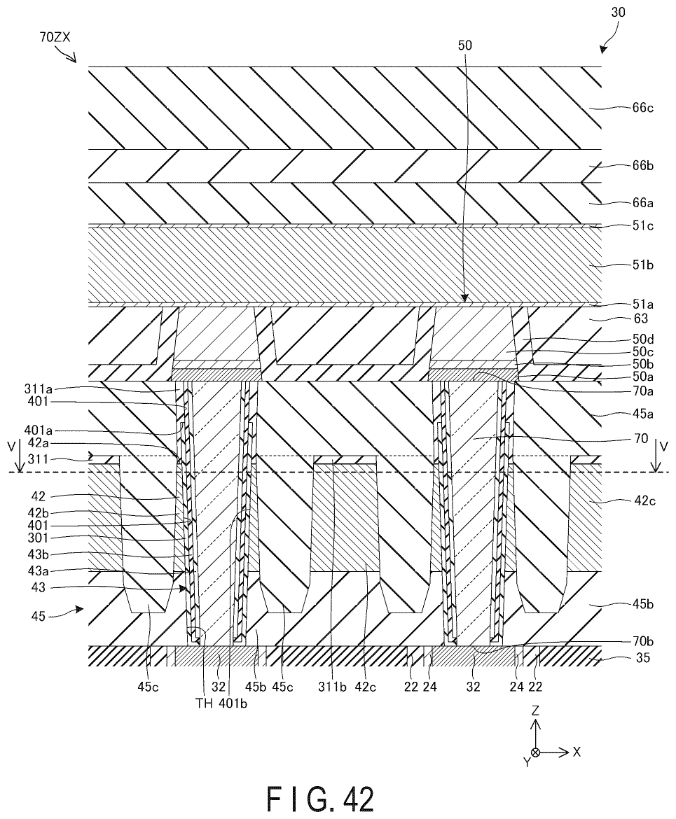

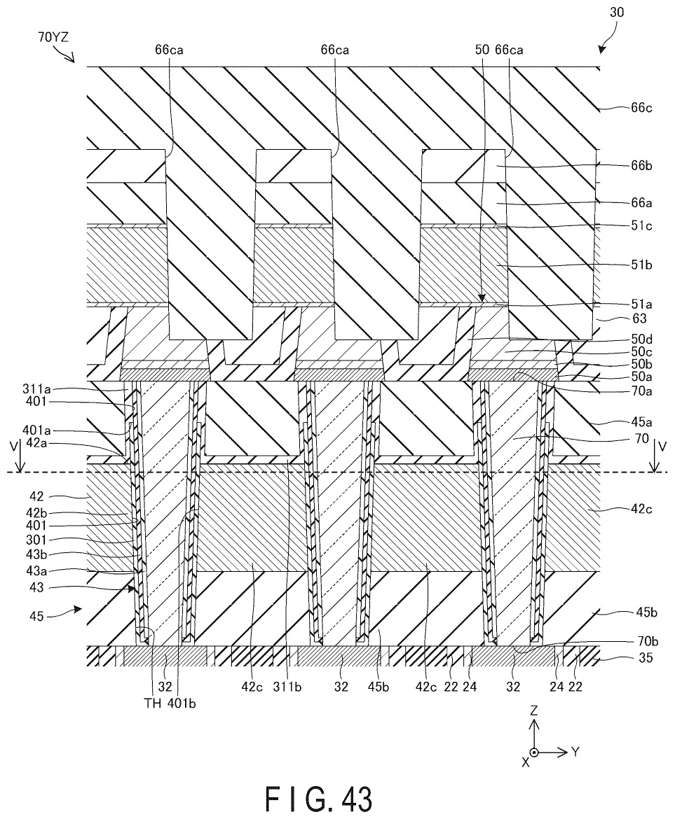

As shown in FIGS. 42 and 43, the semiconductor device 30 of the second example of the first embodiment differs from the semiconductor device 30 of the first example of the first embodiment (shown in FIGS. 3 and 4) in that the stepped surface 401a in the region 401 is located above the surface 42a of the conductive layer 42 but below the lower surface of the upper electrode 50.

### Method for Manufacturing the Semiconductor Device 30 of the Second Example of the First Embodiment

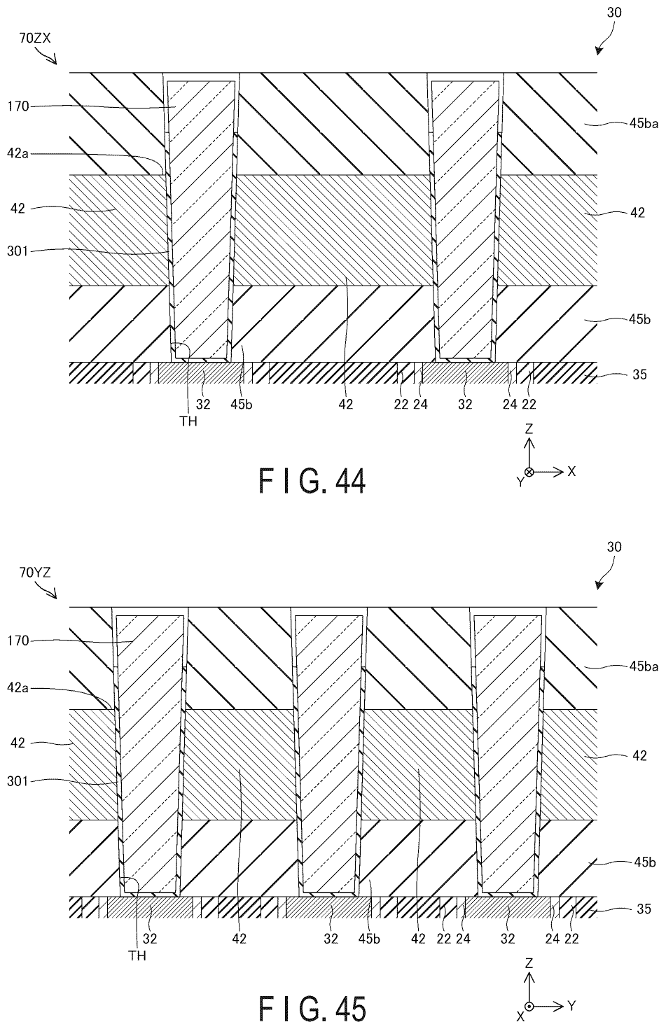

In the method for manufacturing the semiconductor device 30 of the second example of the first embodiment, after the sacrificial amorphous silicon layer 170 is etched back so that a part of the upper portion of the sacrificial amorphous silicon layer 170 is removed (see FIGS. 12 and 13), a part of the upper portion of the liner film 301 is then removed by etching as shown in FIGS. 44 and 45. Thus, the upper end of the liner film 301 is located below the upper end of the sacrificial amorphous silicon layer 170. By controlling the removal amount of the liner film 301, the position of the upper end of the liner film 301 can be adjusted.

The third example of the semiconductor device 30 according to the first embodiment (sometimes referred to as the third example of the first embodiment) will be described below.

### The Third Example of the First Embodiment

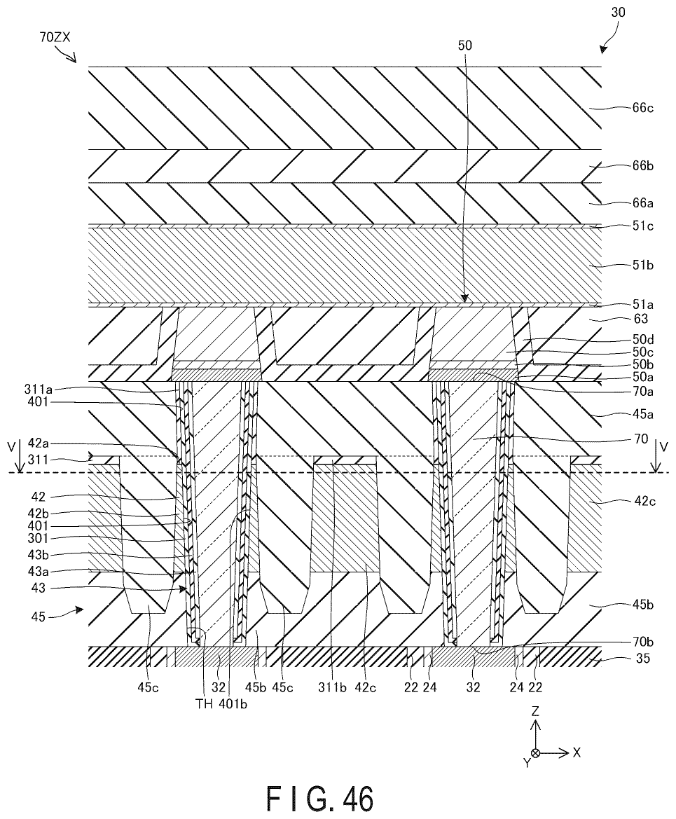

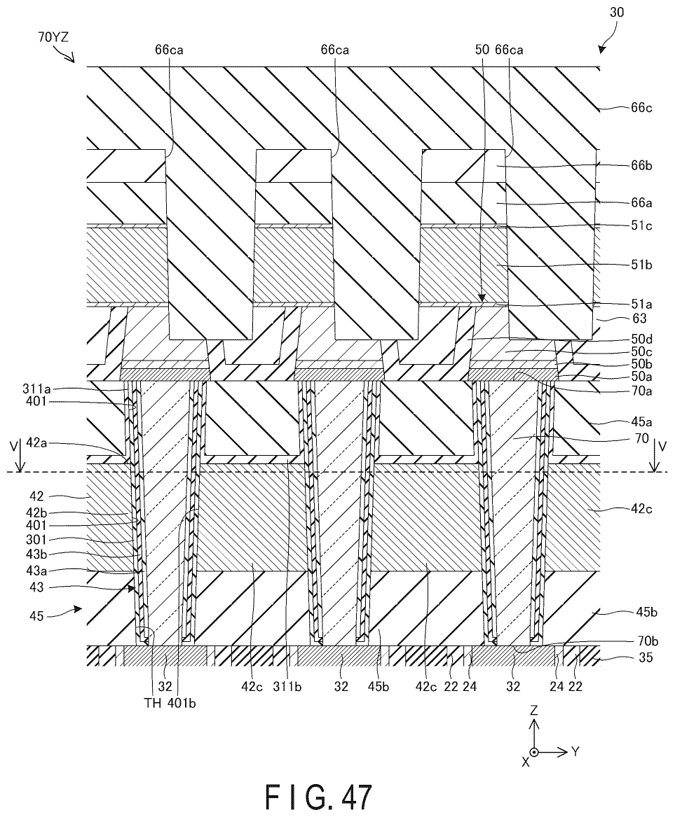

As shown in FIGS. 46 and 47, the semiconductor device 30 of the third example of the first embodiment differs from the semiconductor device 30 of the first example of the first embodiment (shown in FIGS. 3 and 4) in that the upper end of the liner film 301 contacts with the upper electrode 50, and the stepped surface 401a is not formed in the region 401.

### Method for Manufacturing the Semiconductor Device 30 of the Third Example of the First Embodiment

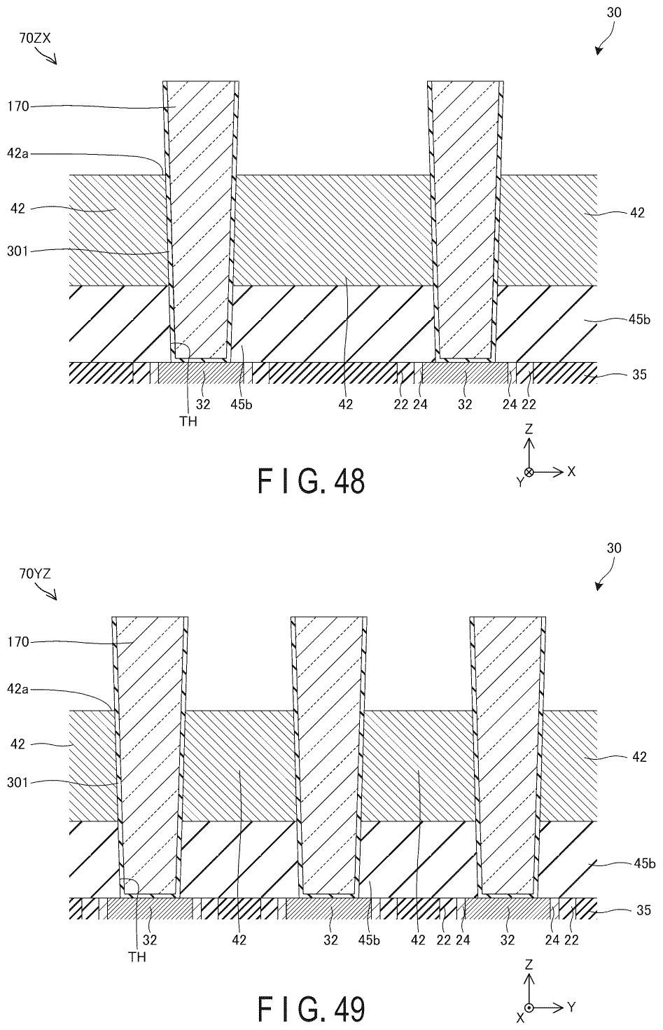

In the method of manufacturing the semiconductor device 30 of the third example of the first embodiment, after the insulating film 45ba is removed, instead of the liner film 301 exposed above the conductive layer 42 being removed by etching (see FIGS. 14 and 15), only the insulating film 45ba is removed by etching, and the liner film 301 exposed above the conductive layer 42 is left. as shown in FIGS. 48 and 49.

The fourth example of the semiconductor device 30 according to the first embodiment (sometimes referred to as the fourth example of the first embodiment) will be described.

### The Fourth Example of the First Embodiment

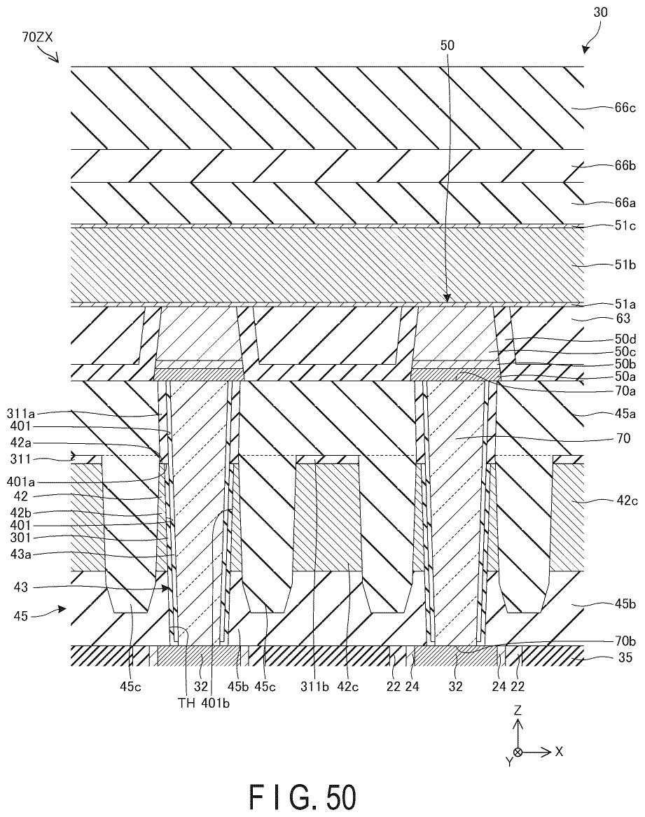

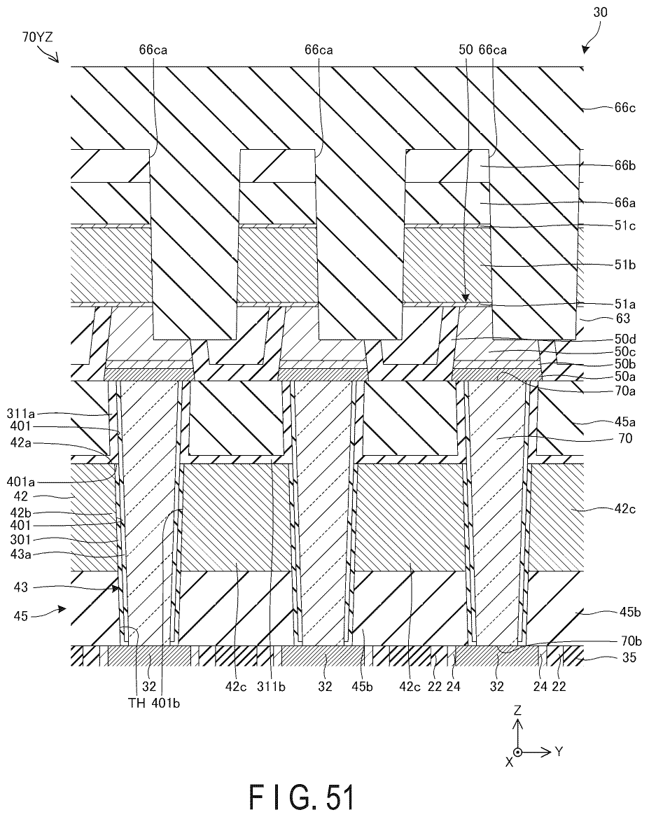

As shown in FIGS. 50 and 51, the semiconductor device 30 of the fourth example of the first embodiment differs from the semiconductor device 30 of the first example of first embodiment (shown in FIGS. 3 and 4) in that the gate insulating film 43 does not include the insulating film 43b.

### Method for Manufacturing the Semiconductor Device 30 of the Fourth Example of the First Embodiment

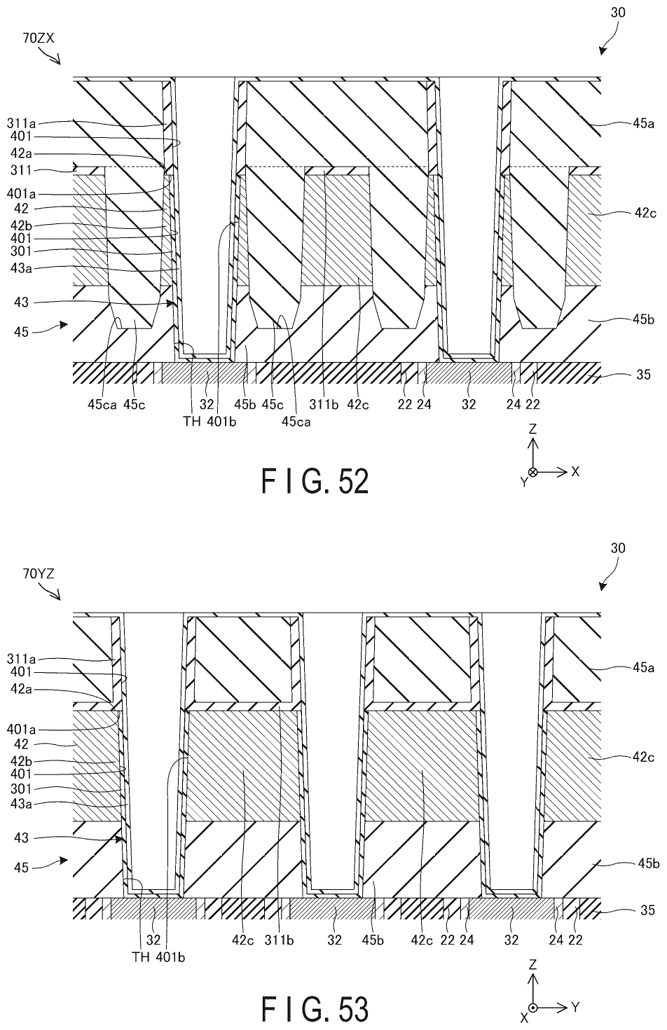

In the method for manufacturing the semiconductor device 30 of the fourth example of the first embodiment, instead of the insulating film 43b is formed above the semiconductor device 30 (see FIGS. 24 and 25), the insulating film 43a is formed above the semiconductor device 30 as shown in FIGS. 52 and 53. This can reduce the number of steps for forming the insulating film 43b comprising silicon nitride.

A fifth example of the semiconductor device 30 according to the first embodiment (sometimes referred to as the fifth example of the first embodiment) will be described.

### The Fifth Example of the First Embodiment

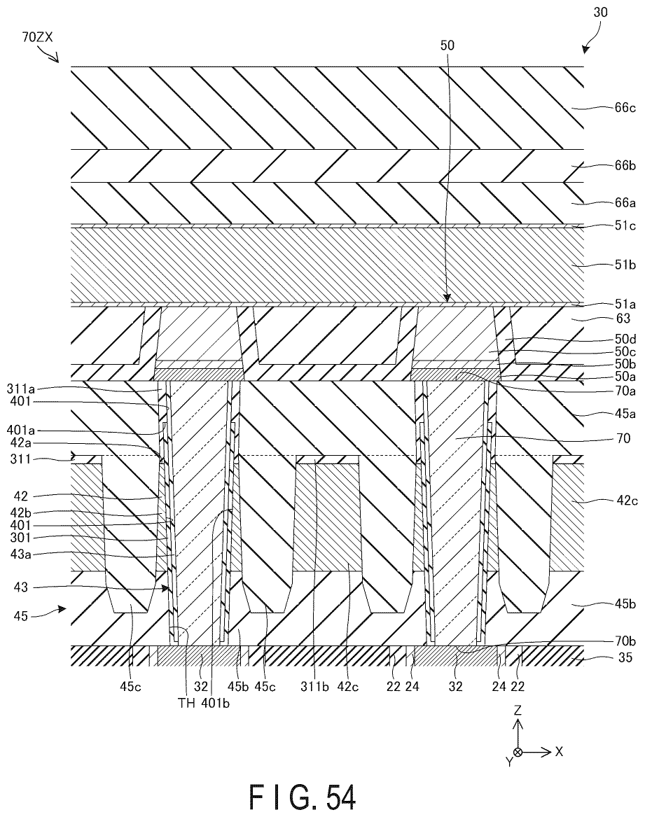

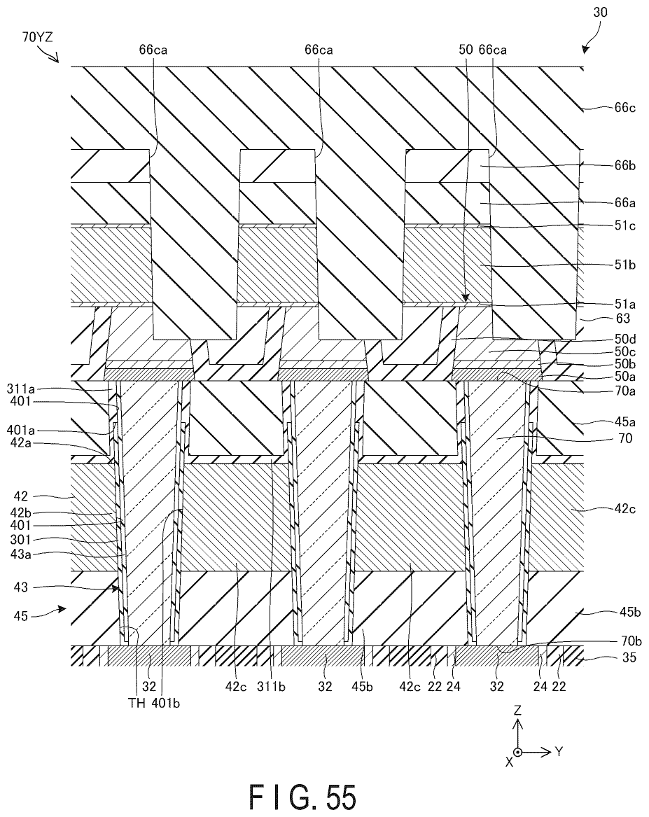

As shown in FIGS. 54 and 55, the semiconductor device 30 of the fifth example of the first embodiment differs from the semiconductor device 30 of the fourth example of the first embodiment (shown in FIGS. 50 and 51) in that the stepped surface 401a in the region 401 is located above the surface 42a of the conductive layer 42 but below the lower surface of the upper electrode 50.

This configuration can reduce the possibility of contact between the conductive layer 42 and the insulating film 43a, thus reducing the increase of gate leakage.

### Method for Manufacturing the Semiconductor Device 30 of the Fifth Example of the First Embodiment

In the method for manufacturing the semiconductor device 30 of the fifth example of the first embodiment, a part of the upper portion of the liner film 301 is removed by etching as shown in FIGS. 44 and 45. Further, as shown in FIGS. 52 and 53, the insulating film 43a is formed above the semiconductor device 30.

A sixth example of the semiconductor device 30 according to the first embodiment (sometimes referred to as the sixth example of the first embodiment) will be described.

### The Sixth Example of the First Embodiment

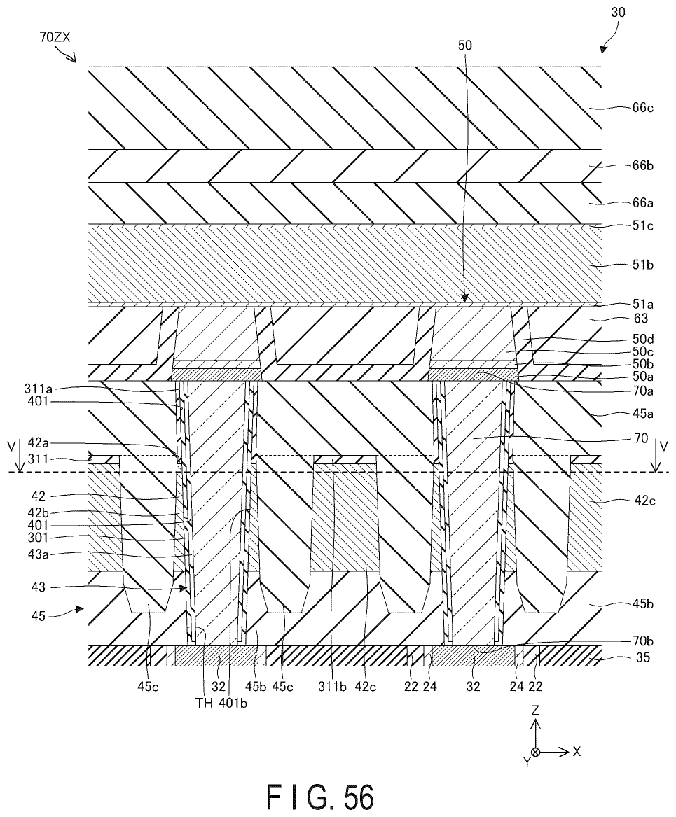

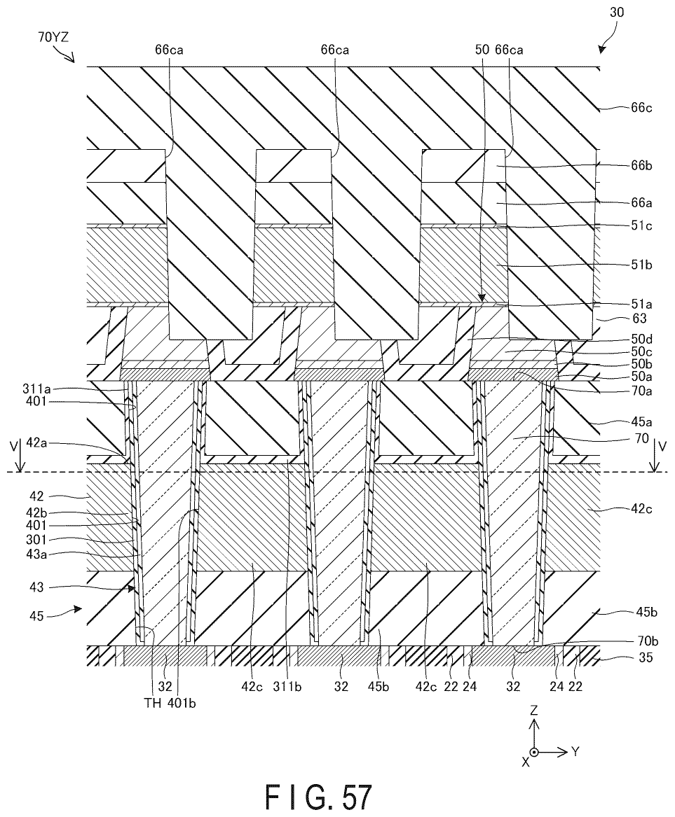

As shown in FIGS. 56 and 57, the semiconductor device 30 of the sixth example of the first embodiment differs from the semiconductor device 30 of the fourth example of the first embodiment (shown in FIGS. 50 and 51) in that the upper end of the liner film 301 contacts with the upper electrode 50, and the stepped surface 401a is not formed in the region 401.

### Method for Manufacturing the Semiconductor Device 30 of the Sixth Example of the First Embodiment

In the method for manufacturing the semiconductor device 30 of the sixth example of the first embodiment, as shown in FIGS. 48 and 49, only the insulating film 45ba is removed by etching, and the liner film 301 exposed above the conductive layer 42 is left. Further, as shown in FIGS. 52 and 53, the insulating film 43a is formed above the semiconductor device 30.

A seventh example of the semiconductor device 30 according to the first embodiment (sometimes referred to as the seventh example of the first embodiment) will be described.

### The Seventh Example of the First Embodiment

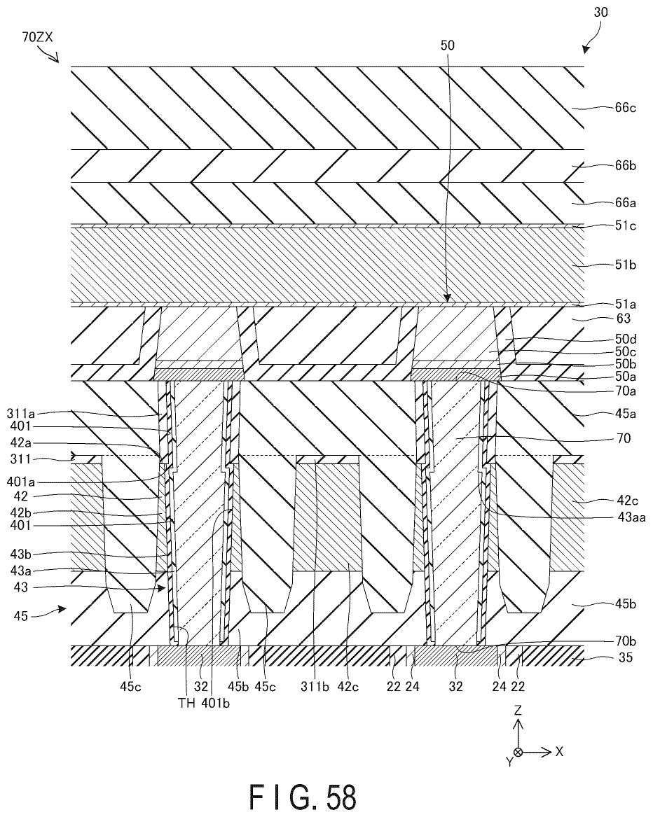

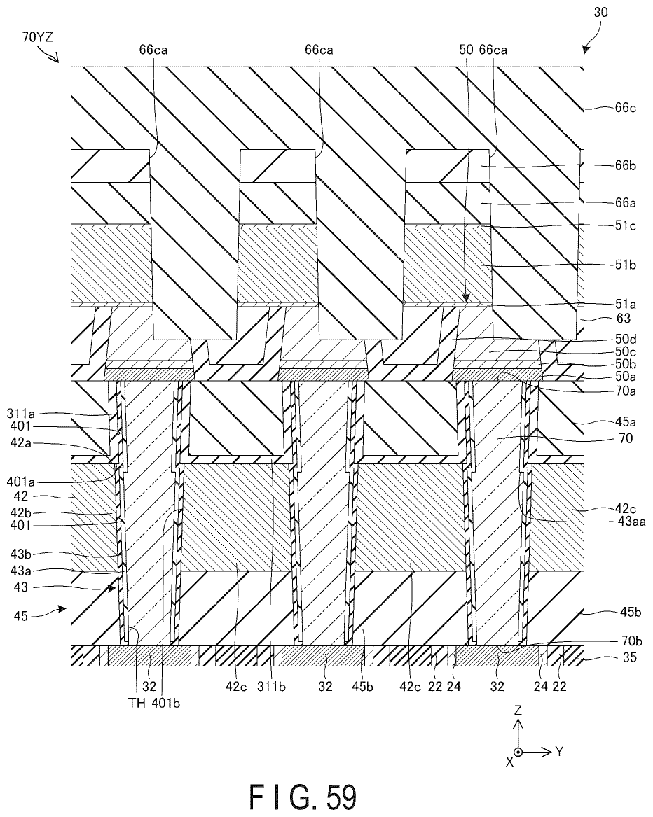

As shown in FIGS. 58 and 59, the semiconductor device 30 of the seventh example of the first embodiment differs from the semiconductor device 30 of the first example of the first embodiment (shown in FIGS. 3 and 4) in that it does not include the liner film 301.

### Method for Manufacturing the Semiconductor Device 30 of the Seventh Example of the First Embodiment

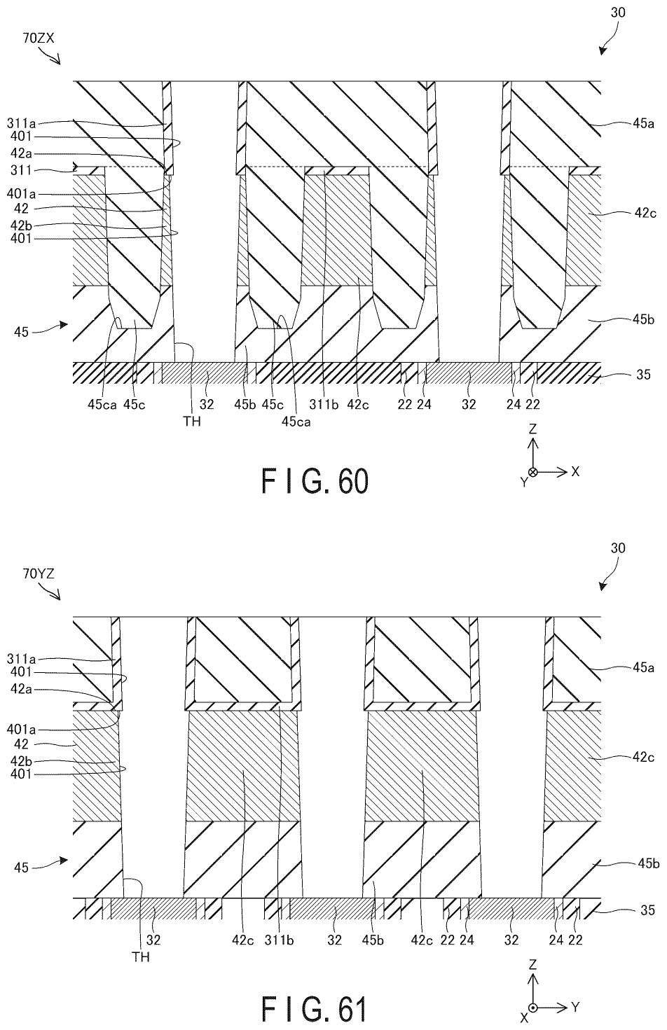

In the method for manufacturing the semiconductor device 30 of the seventh example of the first embodiment, after the sacrificial amorphous silicon layer 170 inside the transistor hole TH is removed by etching (see FIGS. 22 and 23), the liner film 301 is removed by etching as shown in FIGS. 60 and 61.

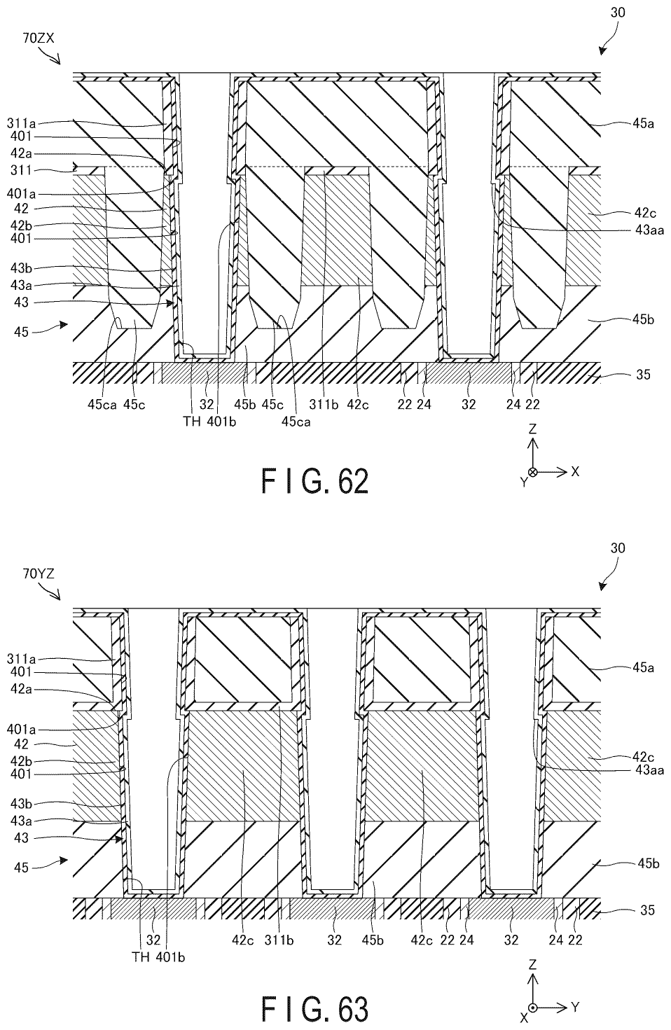

Then, as shown in FIGS. 62 and 63, the insulating film 43b and the insulating film 43a are formed above the semiconductor device 30.

In the semiconductor device 30 of the seventh example of the first embodiment, since the liner film 301 is removed, the insulating film 43b and the insulating film 43a are formed over the inner surface of the cylindrical portion 311a in the spacer film 311, the stepped surface 401a, and the inner surface of the surrounding portion 42b in the conductive layer 42.

Therefore, the inner surface of the insulating film 43a is oriented in the −Z-axis direction and includes a stepped surface 43aa which is annular when viewed from below.

When the semiconductor device 30 is viewed from above, a portion or all of the insulating film 43a opposing the conductive layer 42 cannot be viewed since it is blocked by the stepped surface 43aa. Therefore, when the upper portion of the semiconductor device 30 is etched back by reactive ion etching (see FIGS. 28 and 29), it is possible to suppress some or all of the insulating film 43a opposing the conductive layer 42 from being damaged by the reactive ion etching. This can suppress the generation of gate leakage.

An eighth example of the semiconductor device 30 according to the first embodiment (sometimes referred to as the eighth example of the first embodiment) will be described.

### The Eighth Example of the First Embodiment

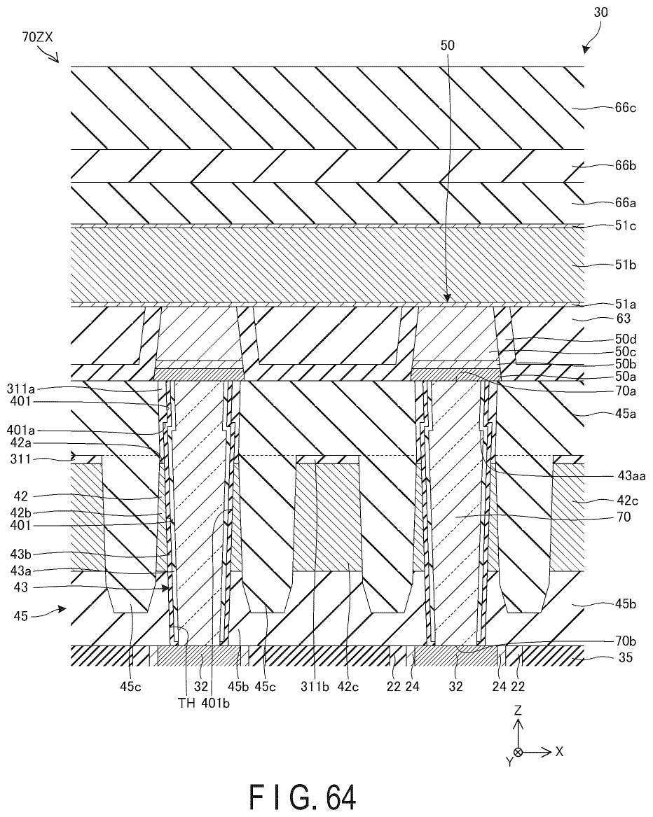

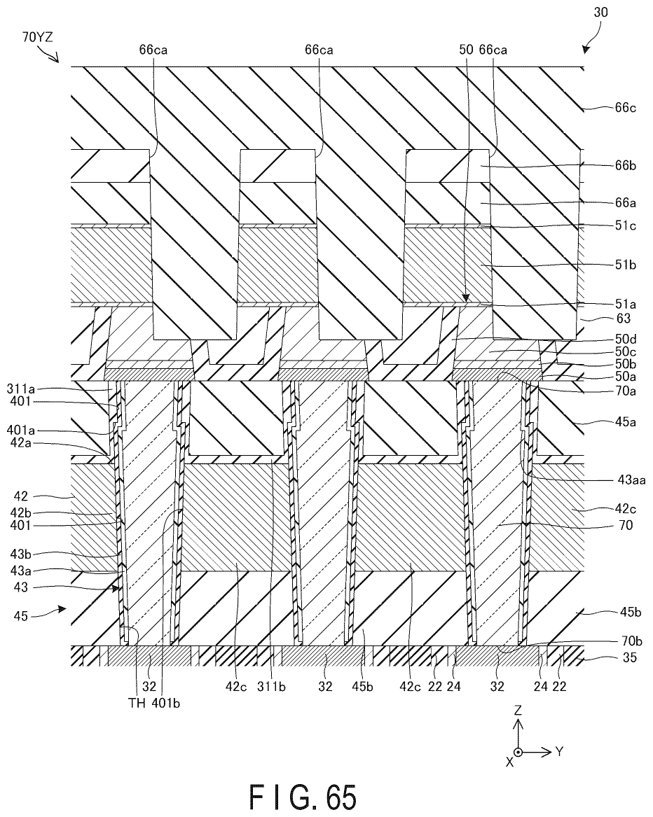

As shown in FIGS. 64 and 65, the semiconductor device 30 of the eighth example of the first embodiment differs from the semiconductor device 30 of the seventh example of the first embodiment (shown in FIGS. 58 and 59) in that the stepped surface 401a in the region 401 is located above the surface 42a of the conductive layer 42 but below the lower surface of the upper electrode 50.

With this configuration, the stepped surface 43aa can be separated from the conductive layer 42, it is thus possible to suppress the generation of gate leakage due to electric field concentration in the stepped surface 43aa.

### Method for Manufacturing the Semiconductor Device 30 of the Eighth Example of the First Embodiment

In the method for manufacturing the semiconductor device 30 of the eighth example of the first embodiment, a part of the upper portion of the liner film 301 is removed by etching as shown in FIGS. 44 and 45. As shown in FIGS. 60 and 61, the liner film 301 is removed by etching. Then, as shown in FIGS. 62 and 63, the insulating film 43b and the insulating film 43a are formed above the semiconductor device 30 in this order.

A ninth example of the semiconductor device 30 according to the first embodiment (sometimes referred to as the ninth example of the first embodiment) will be described below.

### The Ninth Example of the First Embodiment

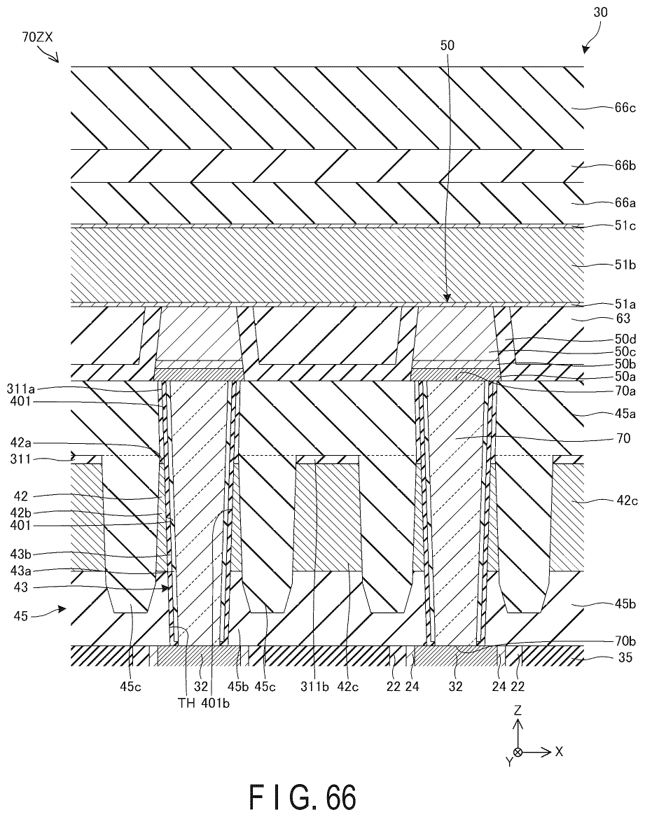

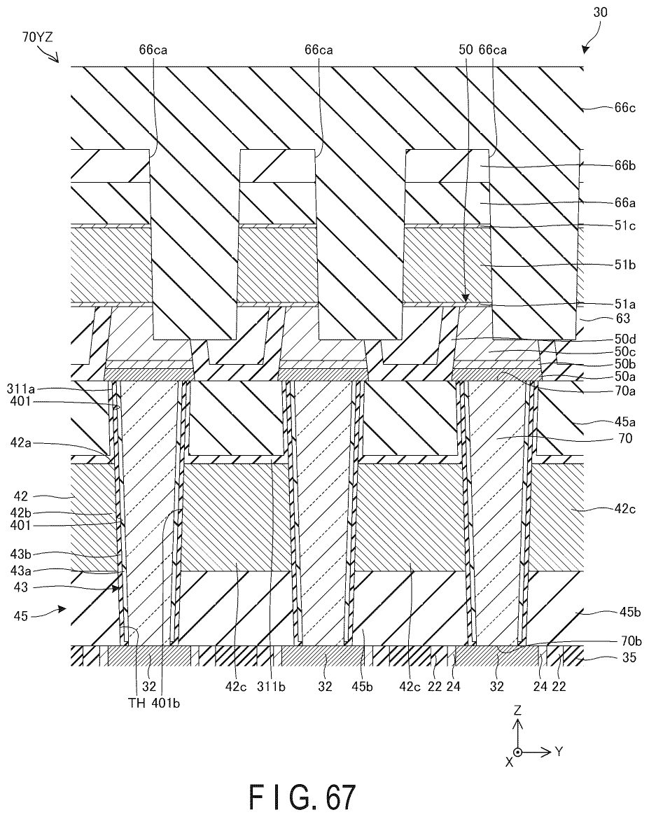

As shown in FIGS. 66 and 67, the semiconductor device 30 of the ninth example of the first embodiment differs from the semiconductor device 30 of the seventh example of the first embodiment (shown in FIGS. 58 and 59) in that the upper end of the liner film 301 contacts with the upper electrode 50, and the stepped surface 401a of the region 401 and the stepped surface 43aa of the insulating film 43a are not formed.

### Method for Manufacturing the Semiconductor Device 30 of the Ninth Example of the First Embodiment

In the method for manufacturing the semiconductor device 30 of the ninth example of the first embodiment, as shown in FIGS. 48 and 49, only the insulating film 45ba is removed by etching, and the liner film 301 exposed above the conductive layer 42 is left. As shown in FIGS. 60 and 61, the liner film 301 is then removed by etching. Then, as shown in FIGS. 62 and 63, the insulating film 43b and the insulating film 43a are formed above the semiconductor device 30 in this order.

### Second Embodiment

A semiconductor device 30B according to the second embodiment will be described. In the second and subsequent embodiments, description of aspects in common with the first embodiment may be omitted, and description will focus the differences. Likewise, similar effects related to similar configurations may not be specifically mentioned for each separate embodiment description.

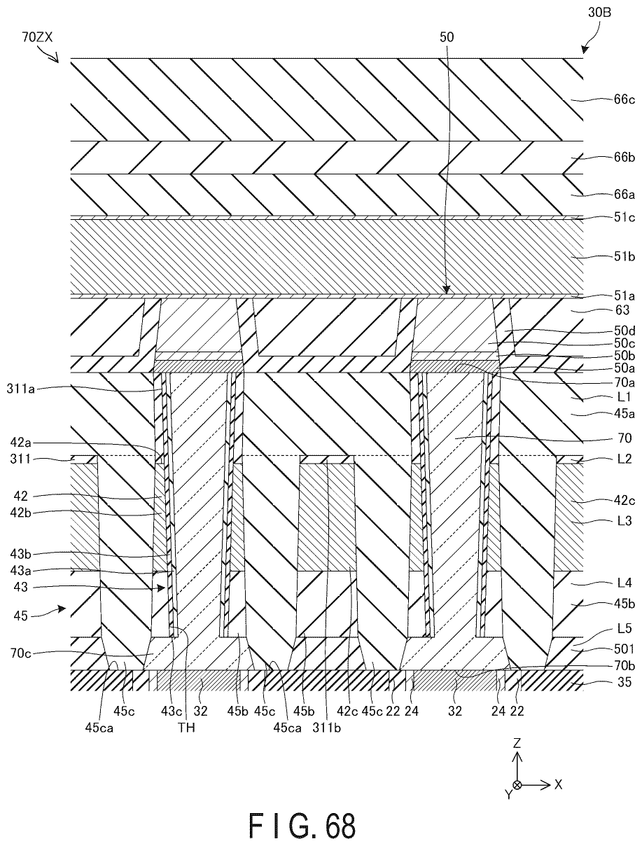

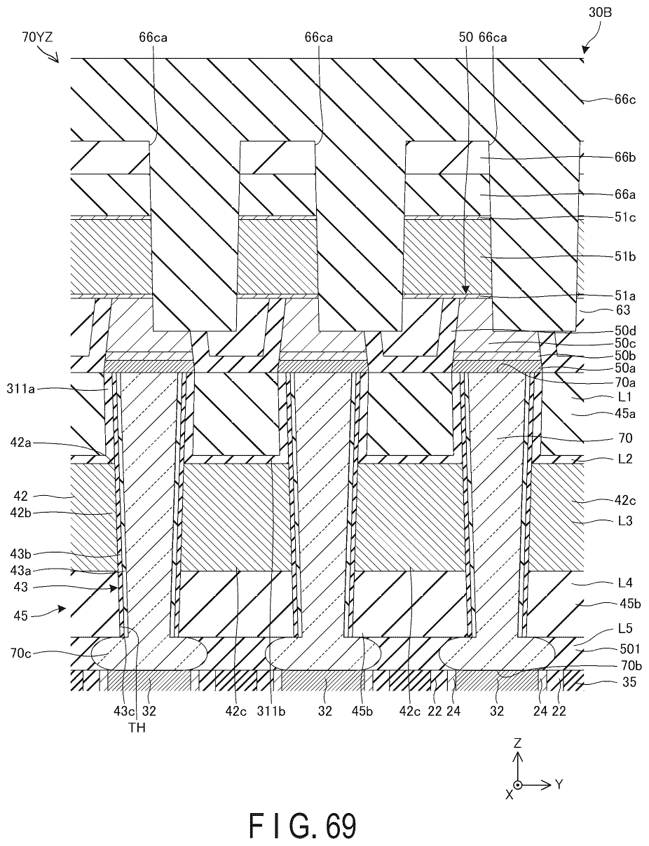

FIG. 68 shows a cross-sectional view of the semiconductor device 30B when viewed in the cross-section 70ZX parallel to ZX plane and included in the oxide semiconductor layer 70. FIG. 69 shows a cross-sectional view of the semiconductor device 30B when viewed in the cross-section 70YZ parallel to YZ plane and included in the oxide semiconductor layer 70.

As shown in FIGS. 68 and 69, the semiconductor device 30B according to the second embodiment includes an insulating film 501 (an example of a fifth insulating film) instead of the liner film 301, as compared with the semiconductor device 30 shown in FIGS. 3 to 5.

The insulating layer 45 includes a layer L1 including the insulating film 45a, a layer L2 including the plate-like portion 311b, a layer L3 (an example of a “first layer”) including the plurality of conductive layers 42, a layer L4 (an example of a “second layer”) including the insulating film 45b (an example of a “fourth insulating film”), and a layer L5 (an example of a “third layer”) including the insulating film 501.

The layers L1, L2, L3, L4, and L5 are provided in this order from the top. The insulating film 45c (an example of a “sixth insulating film”) is located between two conductive layers 42 adjacent in the +X-axis direction, and extends along the +Y-axis direction to divide the layers L2, L3, L4, and L5.

The lower end of the insulating film 45c contacts with the insulating layer 35 (an example of a “seventh insulating film”) provided between two lower electrodes 32.

The insulating film 501 is provided below the insulating film 45b, between two oxide semiconductor layers 70 adjacent in the +Y-axis direction (see FIG. 69).

Further, the insulating film 501 is provided below the insulating film 45b whose two sides are sandwiched by two insulating films 45c, between two oxide semiconductor layers 70 adjacent in the +X-axis direction (see FIG. 68).

The insulating film 501 comprises at least one of the following elements: aluminum, silicon, hafnium, lanthanum, niobium, yttrium, tantalum, vanadium and magnesium, and further includes oxygen. In the present embodiment, the insulating film 501 is an oxide of aluminum (an aluminum oxide). The etching rate of the insulating film 501 is greater than the etching rate of the insulating film 45b.

The gate insulating film 43 surrounds a part of the upper portion of the oxide semiconductor layer 70 along the circumferential direction of the oxide semiconductor layer 70. The oxide semiconductor layer 70 includes, between the lower end 43c of the gate insulating film 43 and the lower electrode 32, a large diameter portion 70c having a diameter larger than the diameter of the gate insulating film 43 at the end 43c.

### Semiconductor Device Manufacturing Method

A method for manufacturing the semiconductor device 30B will be described as an example of a method for manufacturing the semiconductor device according to the second embodiment.

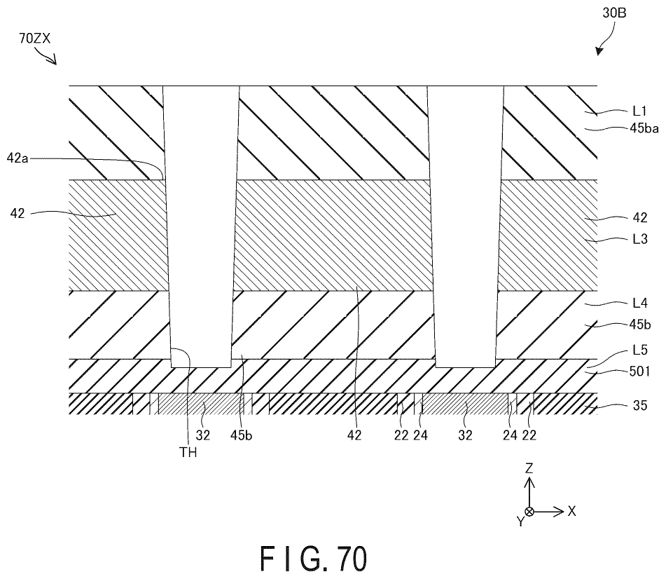

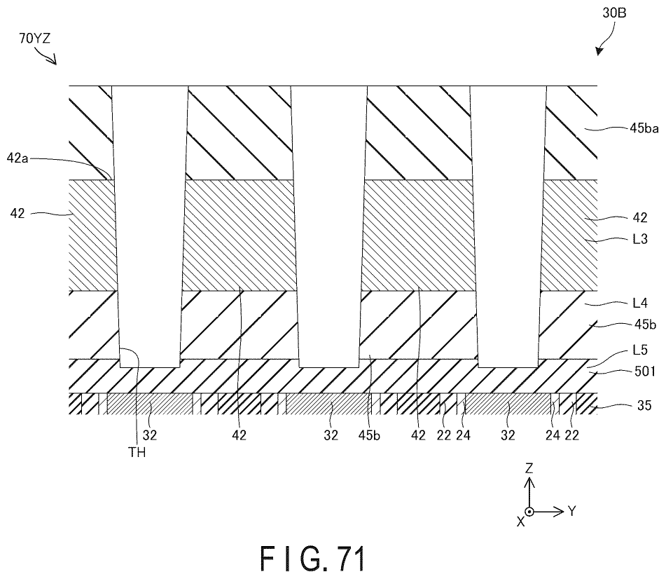

First, as shown in FIGS. 70 and 71, the insulating film 501, the insulating film 45b, the conductive layer 42, and the insulating film 45ba are provided above the insulating layer 35 in this order. The insulating film 501, the insulating film 45b, the conductive layer 42 and the insulating film 45ba extend substantially parallel to XY plane. A transistor hole TH is formed which extends substantially parallel to the Z-axis and penetrates through the insulating film 45ba, conductive layer 42 and insulating film 45b and halfway through the insulating film 501, and then the transistor hole TH is cleaned. At the bottom of the transistor hole TH, the insulating film 501 is exposed, but the lower electrode 32 is not exposed.

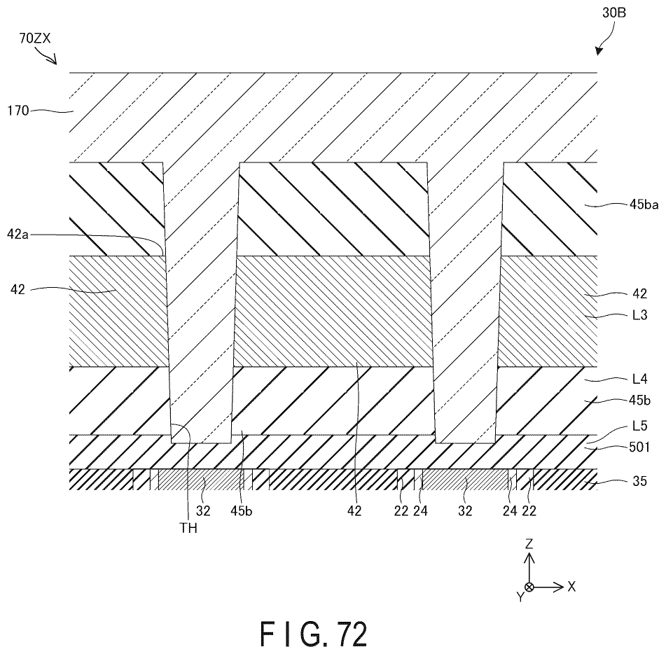

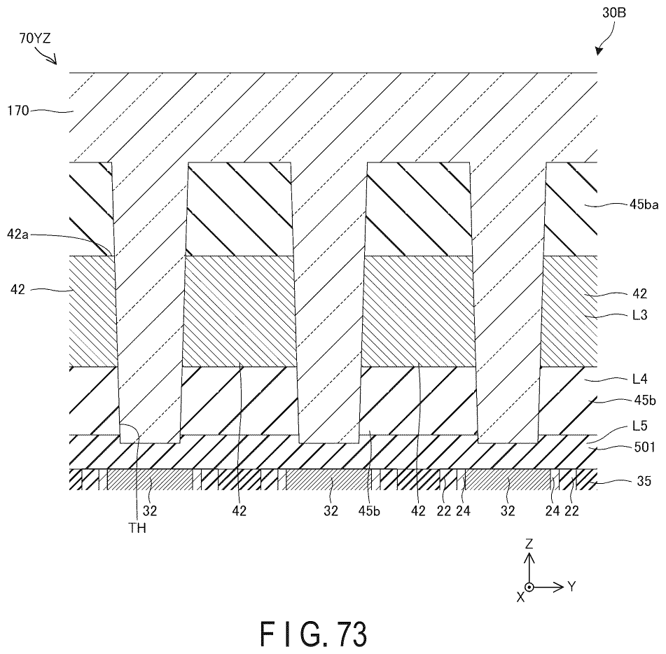

Then, as shown in FIGS. 72 and 73, the sacrificial amorphous silicon layer 170 is formed above the semiconductor device 30B. Thereby, the transistor hole TH is filled with the sacrificial amorphous silicon layer 170.

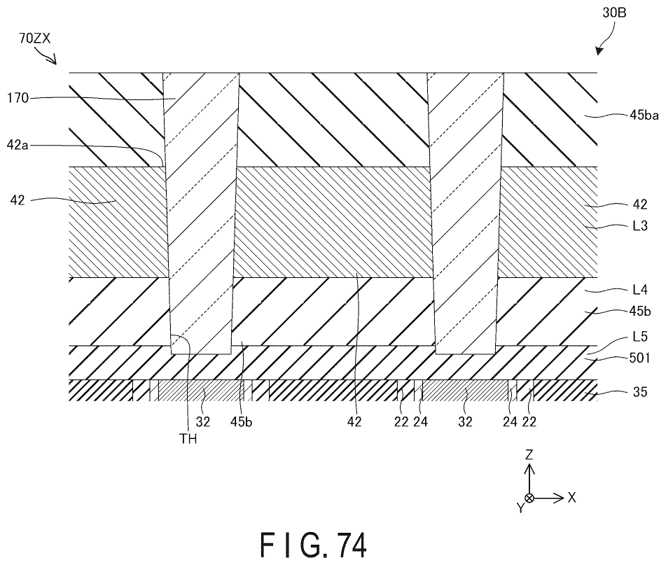

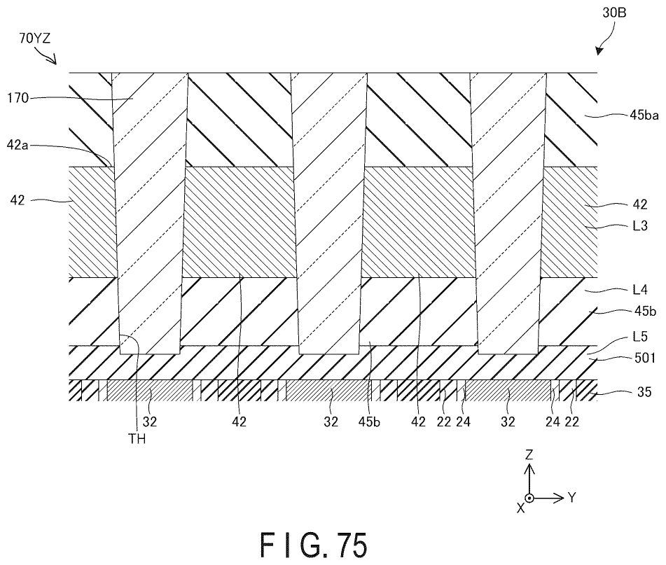

Then, as shown in FIGS. 74 and 75, the sacrificial amorphous silicon layer 170 is etched back, so that a part of the upper portion of the sacrificial amorphous silicon layer 170 is removed, and the upper surface of the insulating film 45ba is exposed.

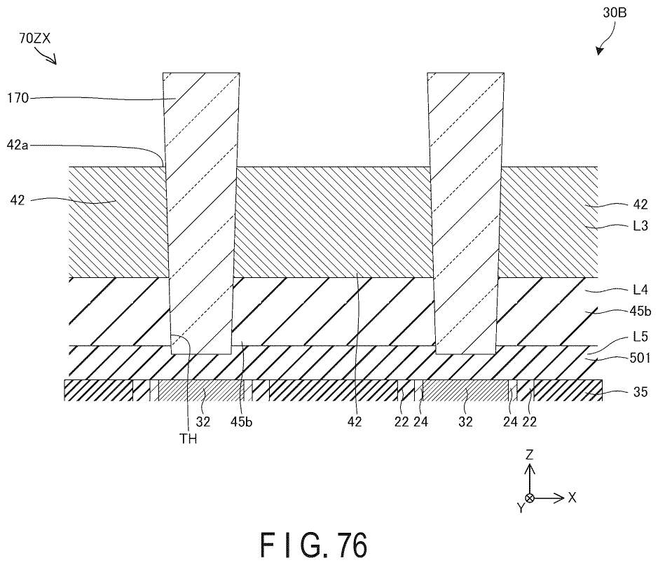

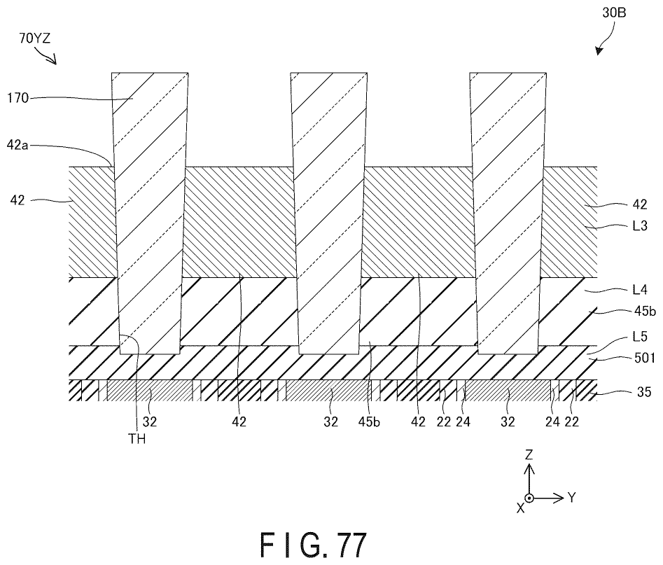

Then, as shown in FIGS. 76 and 77, the insulating film 45ba is removed by etching.

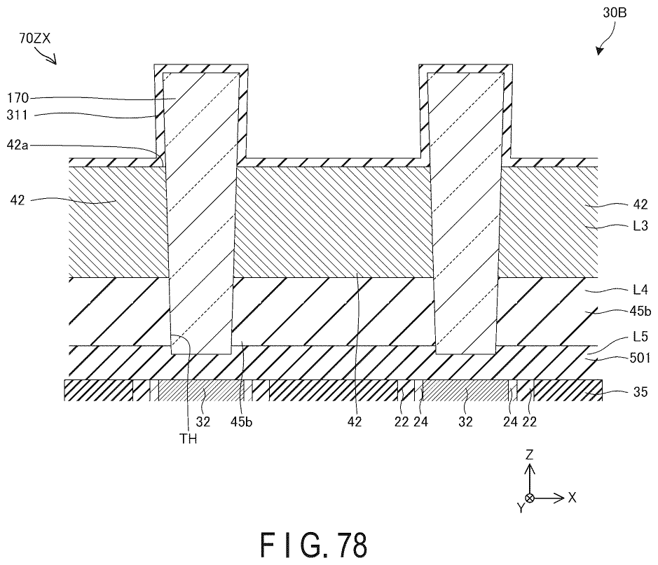

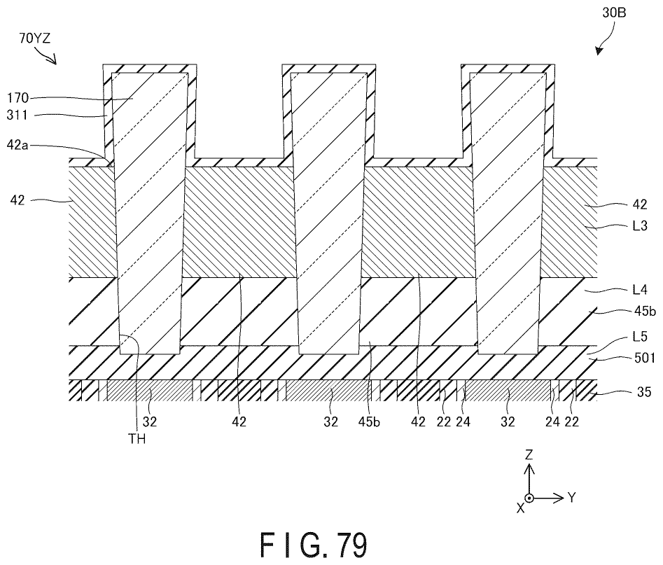

Then, as shown in FIGS. 78 and 79, the spacer film 311 is formed above the semiconductor device 30B. Therefore, the spacer film 311 covers an exposed portion of the sacrificial amorphous silicon layer 170 above the conductive layer 42, and the upper surface 42a of the conductive layer 42.

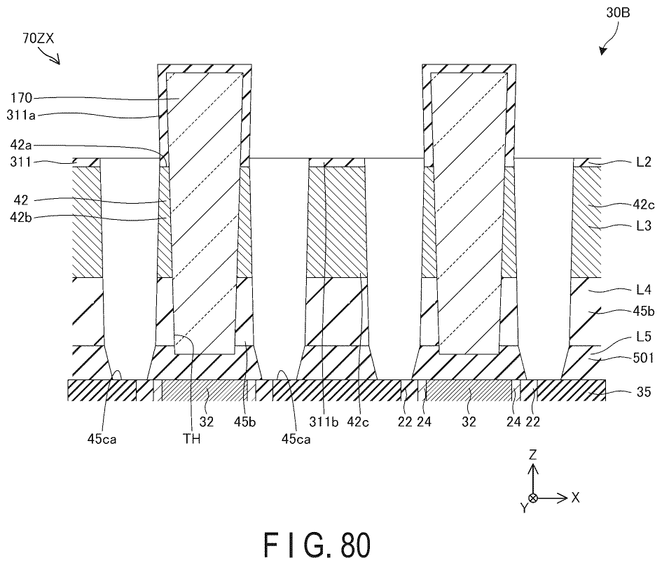

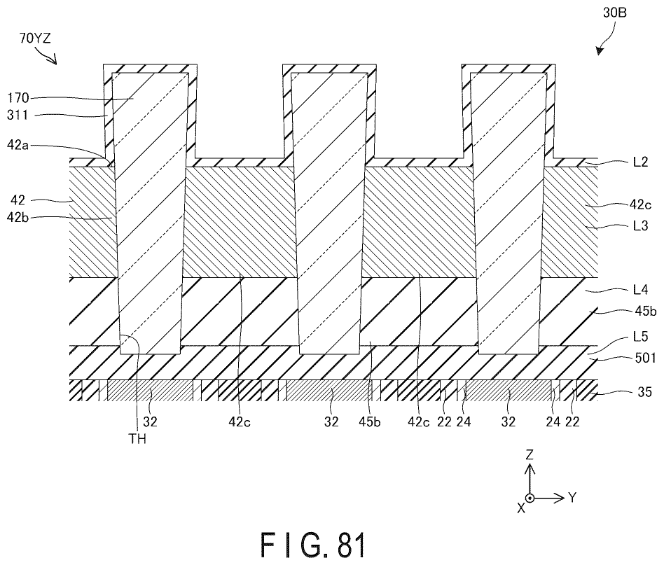

Next, as shown in FIGS. 80 and 81, after deposition, resist coating, exposure, development, peeling, and the like are performed by a lithography method on the surface of the semiconductor device 30B to form a mask, a groove 45ca, which penetrates to the insulating film 501 by etching and extends substantially parallel to the Y-axis, is formed in the semiconductor device 30B. Thereby, the spacer film 311 is separated into the cylindrical portion 311a and the plate-like portion 311b. Further, the conductive layer 42 is separated into a plurality of electrodes which extend substantially parallel to the Y-axis and repeatedly provided in the +X-axis direction. These electrodes correspond to the word lines WL (see FIG. 1).

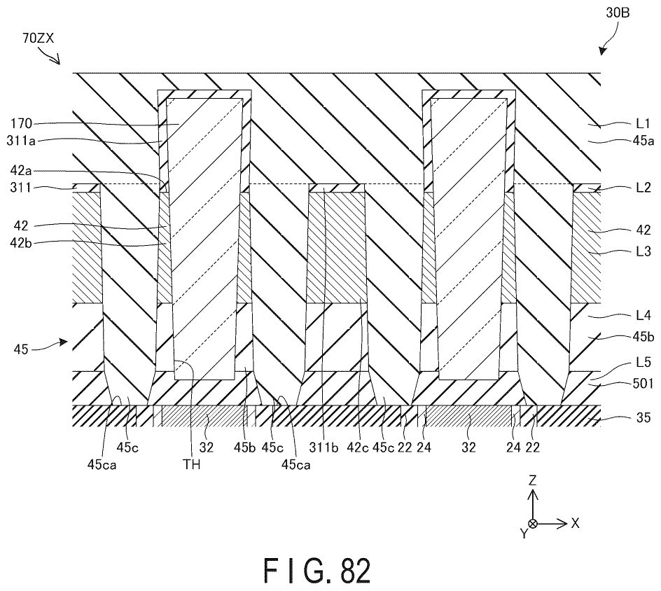

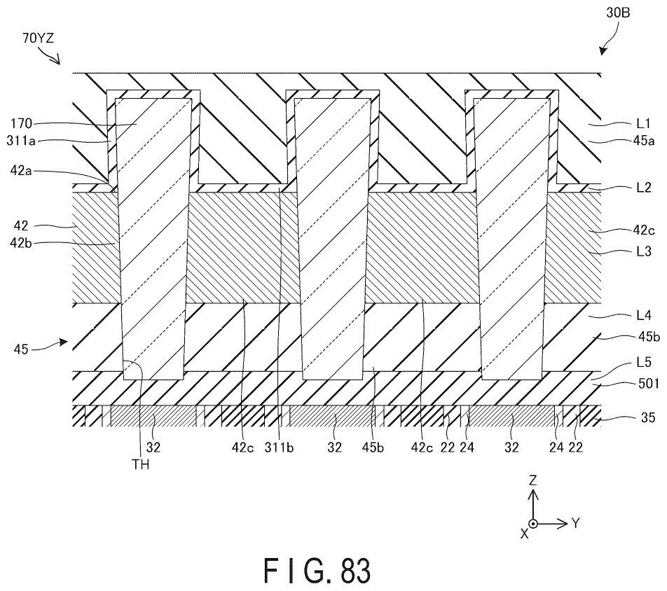

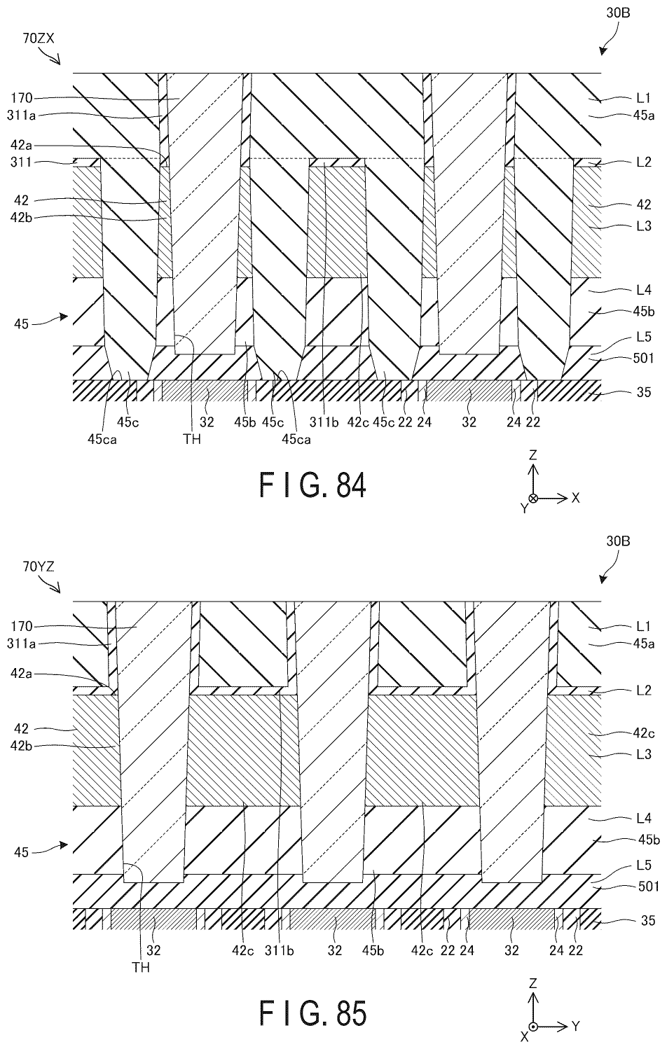

Then, as shown in FIGS. 82 and 83, the insulating films 45c and 45a are integrally formed above the semiconductor device 30B.

Then, the upper surface of the semiconductor device 30B is chemically mechanically polished so that the upper surface of the sacrificial amorphous silicon layer 170 is exposed from the insulating film 45a.

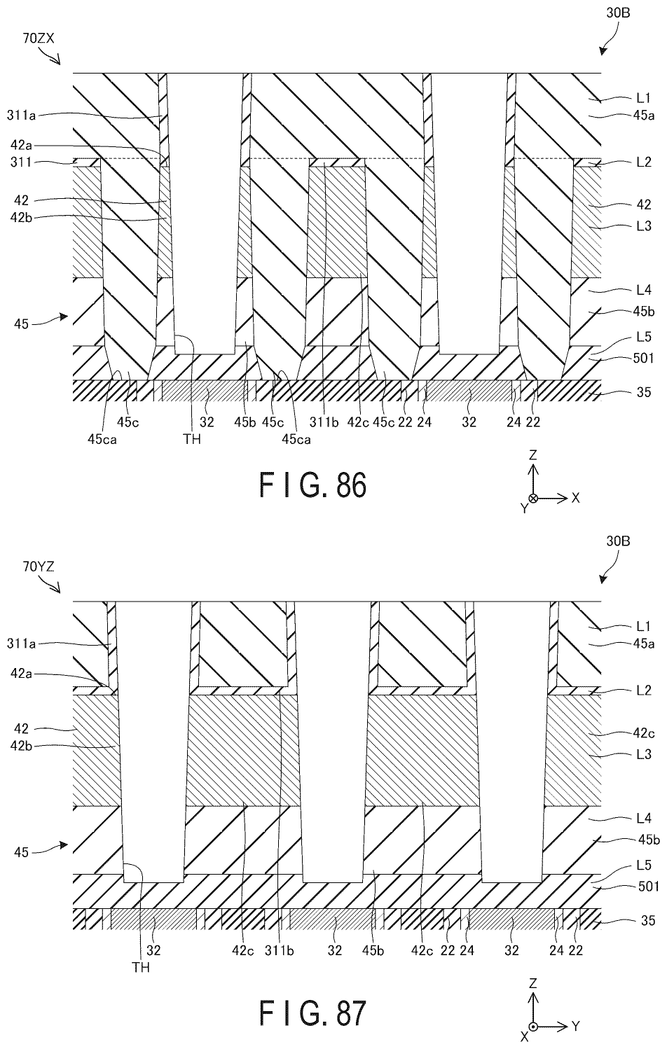

Then, as shown in FIGS. 86 and 87, the sacrificial amorphous silicon layer 170 within the transistor hole TH is removed by etching.

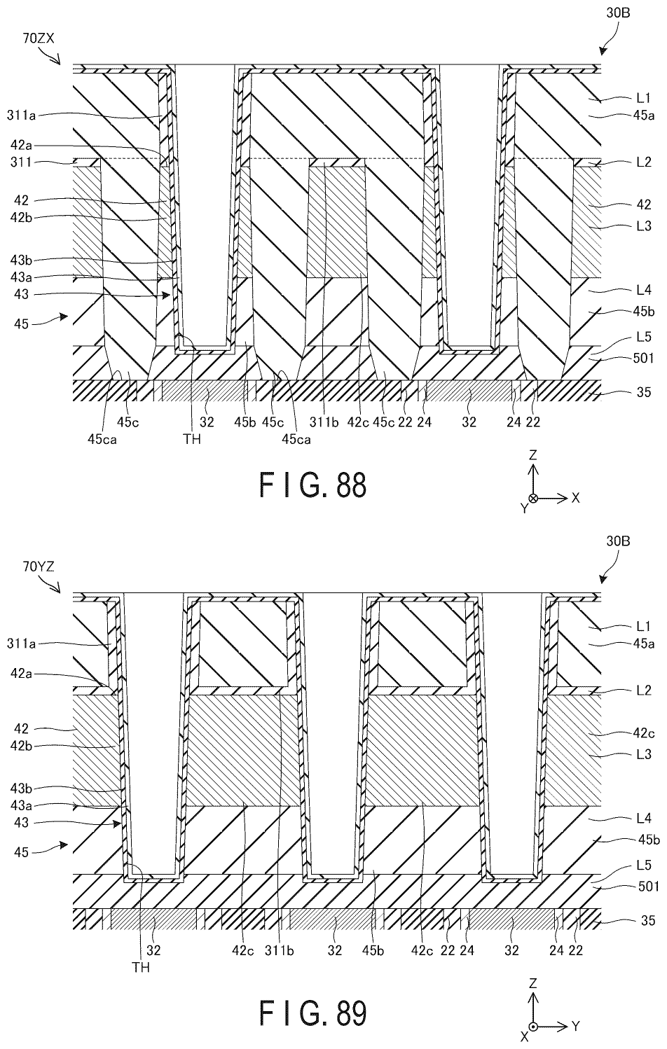

Then, as shown in FIGS. 88 and 89, the insulating film 43b and the insulating film 43a are formed above the semiconductor device 30B in this order.

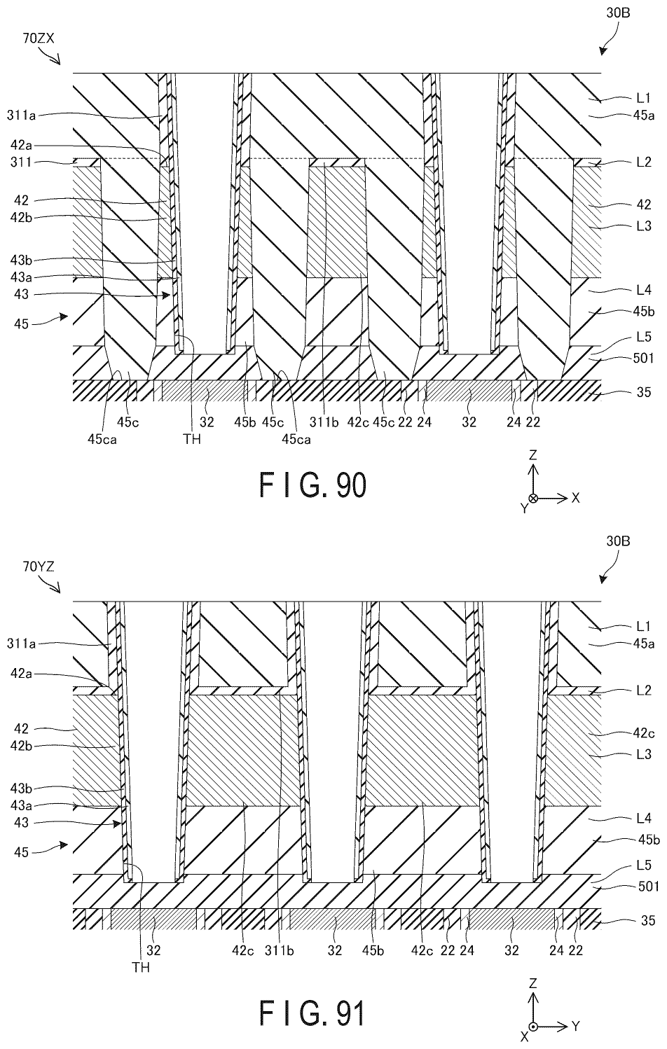

Then, as shown in FIGS. 90 and 91, the upper portion of the semiconductor device 30B is etched back by reactive ion etching so that the insulating film 45a is exposed, and further the insulating film 501 is exposed on the bottom of the transistor hole TH.

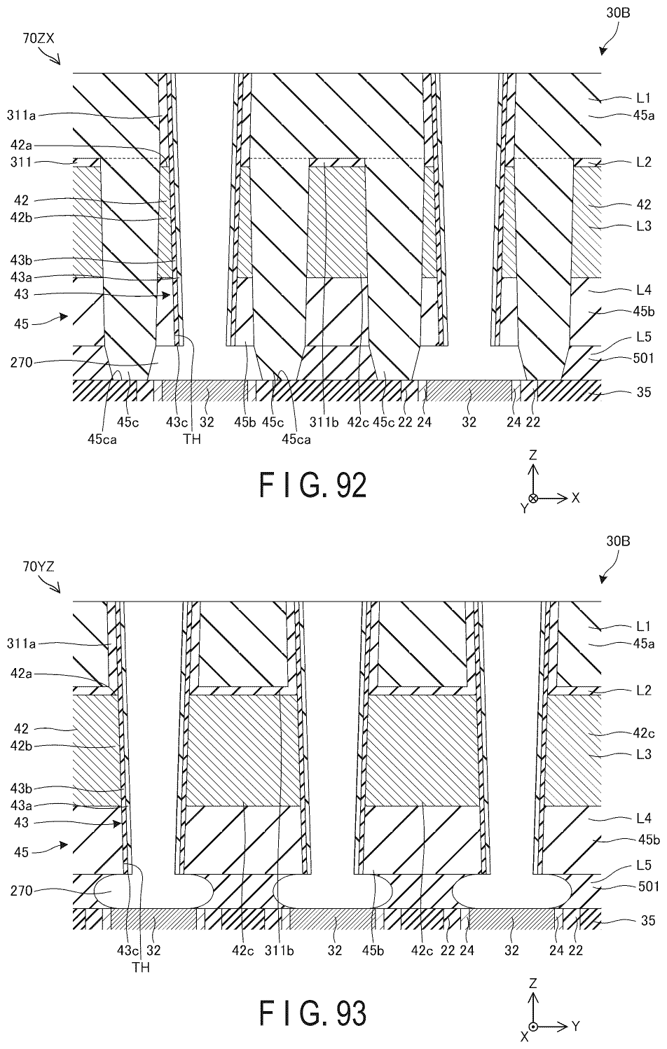

Then, as shown in FIGS. 92 and 93, a portion of the insulating film 501 is removed by wet etching the insulating film 501 exposed to the bottom of the transistor hole TH. Since the etching rate of the insulating film 501 is greater than the etching rate of the insulating film 45b, the removal amount of the insulating film 501 is larger than the removal amount of the insulating film 45b. Then, between the lower end 43c of the gate insulating film 43 and the lower electrode 32, a space 270 having a diameter larger than the diameter of the gate insulating film 43 at the end 43c is formed.

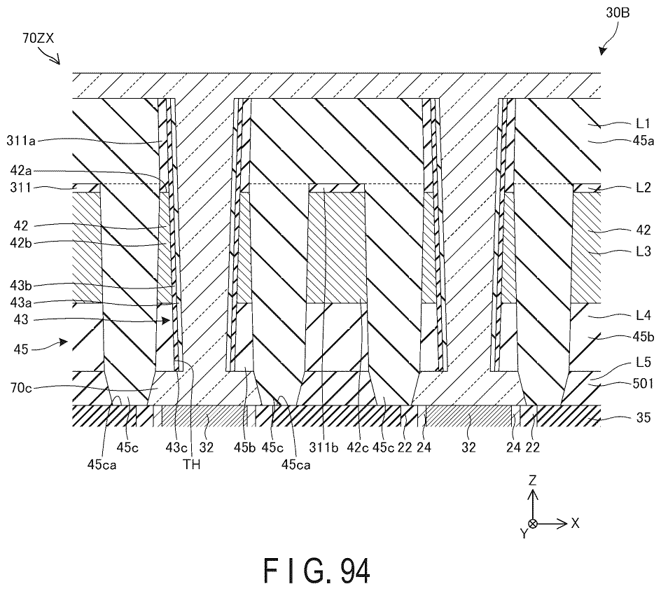

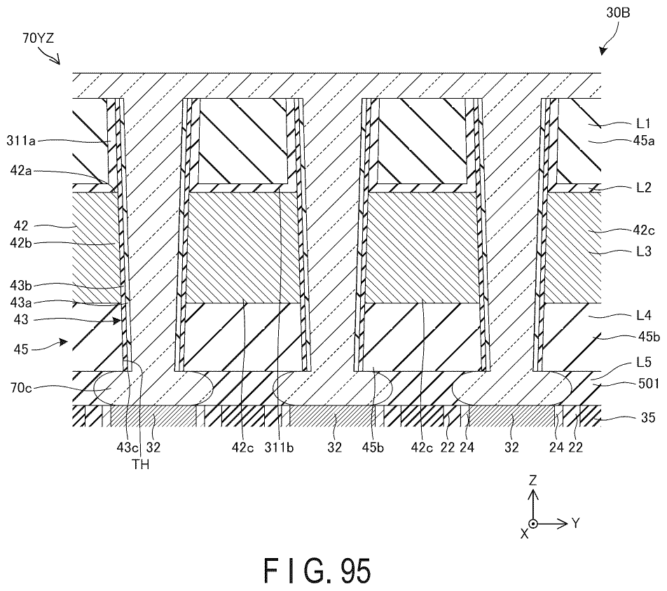

Then, as shown in FIGS. 94 and 95, the oxide semiconductor layer 70 is formed inside the transistor hole TH. At this time, the large diameter portion 70c is formed by the oxide semiconductor layer 70 filled in the space 270.

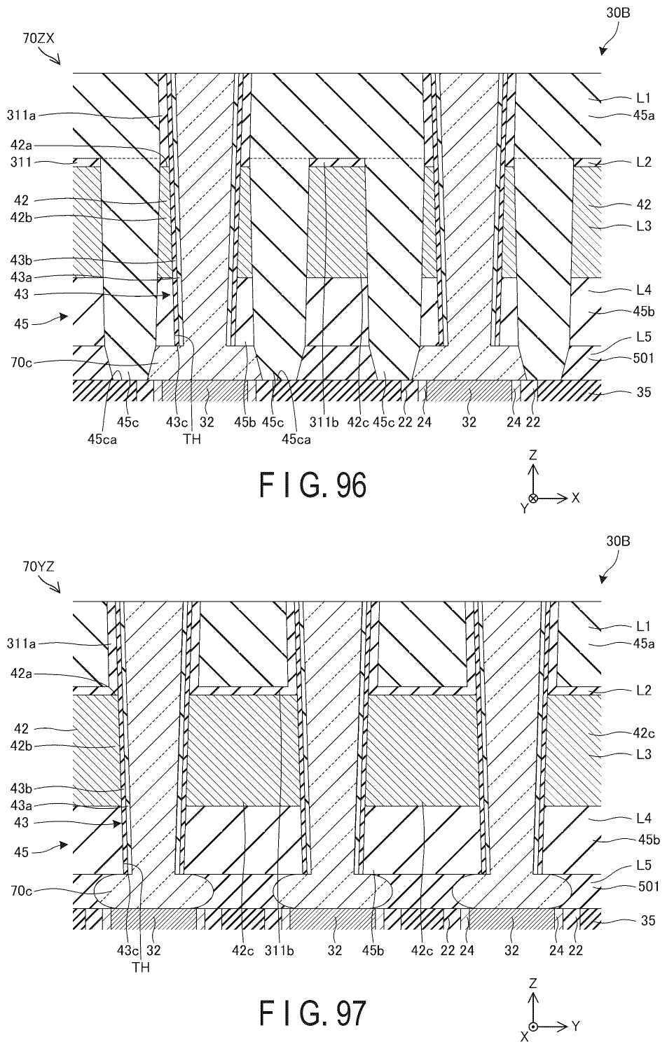

Then, as shown in FIGS. 96 and 97, the upper surface of the semiconductor device 30B is chemically mechanically polished.

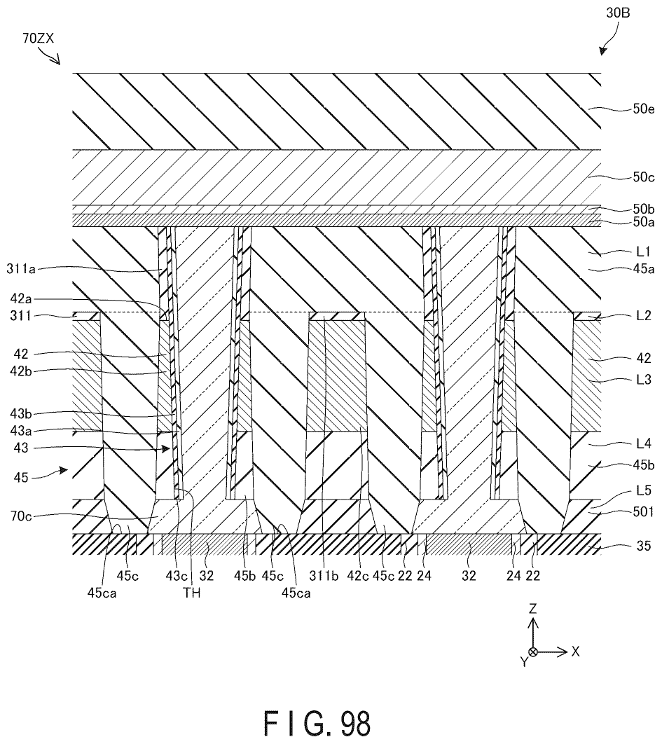

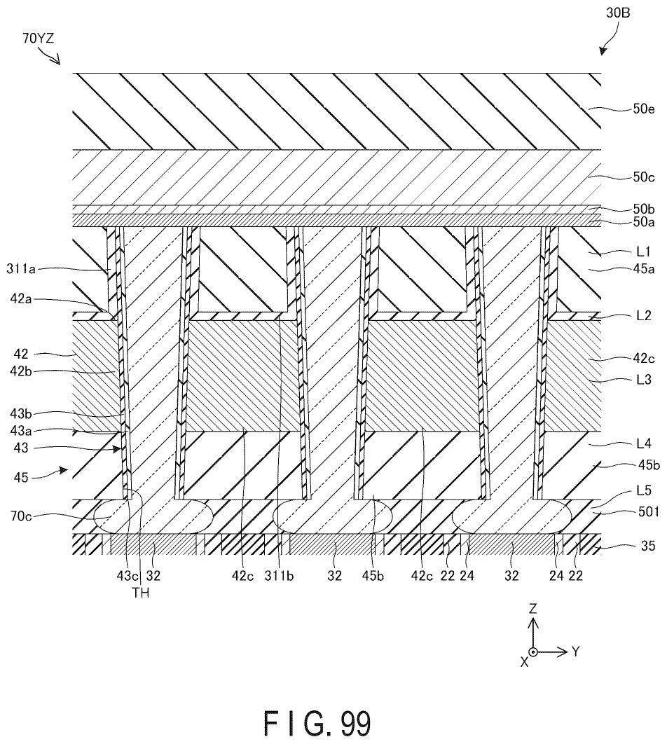

Then, as shown in FIGS. 98 and 99, on the upper surface of the semiconductor device 30B, the metal oxide layer 50a, the barrier metal layer 50b, and the metal film 50c are formed from the bottom to the top. Then, the LPHM film 50e comprising, for example, an oxide of silicon is formed above the metal film 50c.

### Effect

In a case where the insulating film 501 is not formed, if the residue inside the transistor hole TH is removed by a dry or wet process after the transistor hole TH is formed, ITO in the lower electrode 32 may be damaged by a cleaning agent.

In contrast, in the present example, as shown in FIGS. 70 and 71, the lower electrode 32 is not exposed at the bottom of the transistor hole TH, so that it is possible to prevent ITO in the lower electrode 32 from being damaged by the cleaning agent.

In a case where the insulating film 501 is not formed, when the sacrificial amorphous silicon layer 170 is formed above the semiconductor device 30 under a reducing atmosphere, the sacrificial amorphous silicon layer 170 is formed directly on the lower electrode 32 comprising ITO. At this time, silicon whiskers may be generated at the contact portion between the lower electrode 32 and the sacrificial amorphous silicon layer 170.

In contrast, according to the present embodiment, as shown in FIGS. 72 and 73, when the sacrificial amorphous silicon layer 170 is formed, the insulating film 501, not the lower electrode 32, is exposed at the bottom of the transistor hole TH. This can prevent contact between the lower electrode 32 and the sacrificial amorphous silicon layer 170, thereby suppressing the generation of silicon whiskers.

In a case where the insulating film 501 is not formed, when the gate insulating film 43 is formed, tungsten whiskers may be generated since the conductive layer 42 (comprising tungsten) and the lower electrode 32 (comprising ITO) are exposed.

In contrast, according to the present embodiment, as shown in FIGS. 88 and 89, when the gate insulating film 43 is formed, the insulating film 501, not the lower electrode 32, is exposed at the bottom of the transistor hole TH. This can prevent both the conductive layer 42 and the lower electrode 32 from being exposed, thereby suppressing the generation of tungsten whiskers.

Further, the configuration in which the large diameter portion 70c is formed below the oxide semiconductor layer 70, provides a larger contact area between the lower end 70b of the oxide semiconductor layer 70 and the lower electrode 32, so that the contact resistance between the oxide semiconductor layer 70 and the lower electrode 32 can be reduced.

Note that in the semiconductor device 30 of the first to ninth examples of the first embodiment, the configuration in which the stepped surface 401a is provided between the conductive layer 42 and the upper electrode 50 is described, but the present invention is not limited thereto. The stepped surface 401a may be configured to be provided below the surface 42a of the conductive layer 42.

In certain examples, the second electrode comprises at least one of the following elements: indium, tin, zinc, cadmium, gold, silver, platinum, lead, copper, nickel, tungsten, and iron.

In certain examples, the third insulating film contacts with the gate electrode and the second electrode.

In certain examples, the third insulating film comprises at least one of the following elements: silicon, aluminum, zirconium, hafnium, lanthanum, titanium, and strontium, and at least one of oxygen and nitrogen.

In certain examples, the third insulating film is silicon nitride, silicon oxide, silicon oxynitride, aluminum oxide, aluminum nitride, zirconium oxide, hafnium oxide, ruthenium oxide, niobium oxide, yttrium oxide, tantalum oxide, vanadium oxide, magnesium oxide, lanthanum oxide, titanium oxide, or strontium oxide.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
an oxide semiconductor column that extends in a first direction;
a first electrode contacting a first end of the oxide semiconductor column;
a second electrode contacting a second end of the oxide semiconductor column;
a gate electrode that surrounds a portion of the oxide semiconductor column between the first end and the second end of the oxide semiconductor column;
a first insulating film between the gate electrode and the oxide semiconductor column; and
a second insulating film between the gate electrode and the first electrode in the first direction and surrounding the oxide semiconductor column via the first insulating film, wherein
a region in which at least a part of the oxide semiconductor column is accommodated is formed by the gate electrode and the second insulating film, and
the region has a stepped surface facing towards the second electrode.

2. The semiconductor device of claim 1, wherein the first insulating film contacts the first electrode.

3. The semiconductor device of claim 1, wherein the stepped surface is between the gate electrode and the first electrode in the first direction.

4. The semiconductor device of claim 1, wherein an upper surface of the gate electrode meets the stepped surface.

5. The semiconductor device of claim 1, further comprising:
a third insulating film located between the gate electrode and the first insulating film, wherein
the third insulating film contacts the stepped surface.

6. The semiconductor device of claim 1, further comprising:
a plurality of the oxide semiconductors columns spaced from each other along a second direction that intersects the first direction, wherein
the gate electrode extends along the second direction and surrounds each of the plurality of the oxide semiconductors columns via a first insulating film,
the gate electrode includes first portions surrounding the oxide semiconductors columns and second portions connecting two of the first portions, and
each of the second portions is narrower in width than the first portions.

7. The semiconductor device according to claim 1, wherein the oxide semiconductor column is InGaZnO material.

8. The semiconductor device according to claim 1, wherein
the first insulating film is silicon nitride, and
the second insulating film is silicon oxide.

9. A semiconductor device, comprising:
a plurality of oxide semiconductor columns that each extend in a first direction and are spaced from each other in a second direction intersecting the first direction;
a plurality of first electrodes respectively contacting first ends of the plurality of oxide semiconductor columns;
a plurality of second electrodes respectively contacting second ends of the plurality of the oxide semiconductor columns;
a gate electrode extending along the second direction and surrounding the oxide semiconductor columns;
a first insulating film between the gate electrode and each of the oxide semiconductor columns respectively;
a fourth insulating film between the gate electrode and the plurality of second electrodes; and
a fifth insulating film between adjacent oxide semiconductor columns in the second direction and below the fourth insulating film in the first direction, wherein
the fifth insulating film has a composition different from the fourth insulating film.

10. The semiconductor device of claim 9, wherein
the fourth insulating layer is silicon oxide, and
the fifth insulating layer is aluminum oxide.

11. The semiconductor device of claim 9, further comprising:
a plurality of the gate electrodes spaced from each other in a third direction which intersects the first direction and the second direction.

12. The semiconductor device of claim 11, wherein
a first layer includes the plurality of the gate electrodes,
a second layer includes the fourth insulating film,
a third layer includes the fifth insulating film, and
a sixth insulating film is between adjacent oxide semiconductor columns in the third direction and extends along the second direction to divide the first layer, the second layer, and the third layer.

13. The semiconductor device of claim 12, further comprising:
a seventh insulating film between the second electrodes, wherein
the sixth insulating film contacts the seventh insulating film.

14. The semiconductor device of claim 9, wherein
the gate electrode includes first portions surrounding the oxide semiconductor columns and second portions connecting two of the first portions, and
each of the second portions is narrower in width than the first portions.

15. The semiconductor device of claim 9, wherein the fifth insulating film comprises an oxide of at least one of the following elements: aluminum, silicon, hafnium, lanthanum, niobium, yttrium, tantalum, vanadium, and magnesium.

16. A semiconductor device, comprising:
an oxide semiconductor column that has a first end and a second end and extends in a first direction from the second end to the first end;
a first electrode contacting the first end;
a second electrode contacting the second end;
a first insulating film that surrounds the circumference of the oxide semiconductor column; and
a gate electrode that surrounds the oxide semiconductor column at a position between the first end and the second end of the oxide semiconductor column, the first insulating film being between the gate electrode and the oxide semiconductor column, wherein
the oxide semiconductor column includes a large diameter portion having a diameter larger than a diameter of another portion of the oxide semiconductor column.

17. A semiconductor memory device, comprising:
a semiconductor device of claim 1;
a first capacitor electrode connected to the first electrode or the second electrode;
a second capacitor electrode facing the first capacitor electrode; and
a dielectric film between the first capacitor electrode and the second capacitor electrode.

18. A semiconductor memory device, comprising:
a semiconductor device of claim 9;
a first capacitor electrode connected to one of the plurality of first electrodes or one of the plurality of the second electrodes;
a second capacitor electrode facing the first capacitor electrode; and
a dielectric film between the first capacitor electrode and the second capacitor electrode.

19. A semiconductor memory device, comprising:
a semiconductor device of claim 16;
a first capacitor electrode connected to the first electrode or the second electrode;
a second capacitor electrode facing the first capacitor electrode; and
a dielectric film between the first capacitor electrode and the second capacitor electrode.
